(19) United States
(12) Patent Application Publication
(10) Pub. No.: US 2025/0062230 A1
(43) Pub. Date: Feb. 20, 2025

(54) STACKED DECK INTERCONNECT STRUCTURES FOR MICROELECTRONIC DEVICES AND RELATED METHODS

(71) Applicant: Micron Technology, Inc., Boise, ID (US)

(72) Inventor: Darwin A. Clampitt, Wilder, ID (US)

(21) Appl. No.: 18/766,403

(22) Filed: Jul. 8, 2024

Related U.S. Application Data
(60) Provisional application No. 63/520,055, filed on Aug. 16, 2023.

(51) Int. Cl. H01L 23/528; G11C 16/04; H10B 41/10; H10B 41/20; H10B 43/10; H10B 43/20

(52) U.S. Cl. CPC H01L 23/5283; G11C 16/0483; H01L 23/528; H10B 41/10; H10B 41/20; H10B 43/10; H10B 43/20

(57) ABSTRACT

A microelectronic device includes a first deck, a second deck, and a first conductive structure. The first deck has one or more memory cell strings and a stack of data lines operably connected to the one or more memory cell strings. Each of the one or more memory cell strings includes a first conductive contact. The second deck is vertically adjacent to the first deck and includes stacked tiers of conductive material defining a first interconnect structure. The first interconnect structure is operably connected to a data line of the stack of data lines. The first conductive structure is electrically coupled to the first conductive contact of the first deck and to the first interconnect structure of the second deck. Methods of forming the microelectronic device are also disclosed, as are memory devices, electronic signal processor devices, and electronic systems comprising such microelectronic devices.

### CROSS-REFERENCE TO RELATED APPLICATION

This application claims the benefit under 35 U.S.C. § 119(e) of U.S. Provisional Patent Application Ser. No. 63/520,055, filed Aug. 16, 2023, the disclosure of which is hereby incorporated herein in its entirety by this reference.

### TECHNICAL FIELD

Embodiments of the disclosure relate to the field of semiconductor device design, including interconnect structures and fabrication. More specifically, embodiments of the disclosure relate to stacked interconnect structures and to related electronic devices, electronic systems, and methods.

### BACKGROUND

Generally, interconnect structures may be found in integrated circuits, including microprocessors and memory modules. An interconnect structure may provide connections between components, for example transistors and memory devices, in an integrated circuit. In some examples, a local interconnect structure couples two or more integrated circuit devices, e.g., memory devices and/or circuit components, to one another. In other examples, a global interconnect structure couples two or more integrated circuit blocks to one another.

Scaling up the quantity of components in an integrated circuit die, for example, may enable high density logic and memory applications. However, as components are increased in quantity, optimizing spacing and connectivity between microelectronic device components and peripheral circuits becomes challenging.

### BRIEF DESCRIPTION OF THE DRAWINGS

For a detailed understanding of the disclosure, reference should be made to the following detailed description, taken in conjunction with the accompanying drawings, in which like elements have generally been designated with like numerals, and wherein:

FIG. 1 is a simplified, partial schematic diagram of a memory device having sets of data lines, according to embodiments of the disclosure.

FIG. 2 is a simplified, partial schematic diagram of a portion of the memory device of FIG. 1 according to embodiments of the disclosure.

FIG. 3 is a simplified, partial top view of the memory device of FIG. 1, including data lines and conductive contacts (e.g., drain contacts) of respective memory cell strings and interconnect lines with respective landing pads according to some embodiments described herein.

FIG. 4 is a simplified, partial isometric view of the memory device of FIG. 3, including stacks of data lines, respective data line landing pads, a stack of interconnect lines, and respective interconnect line landing pads according to some embodiments described herein.

FIG. 5 is a simplified, partial top view of the memory device of FIG. 1, including hard masks and conductive contacts that have been formed on the memory device.

FIG. 6-FIG. 22B are simplified views of a microelectronic device structure during processing stages of a method of forming a microelectronic device according to some embodiments described herein.

FIG. 23 is a simplified, partial schematic diagram of a portion of an electronic signal processor device structure according to embodiments of the disclosure.

FIG. 24 is a simplified, partial schematic diagram depicting multiple stacked decks of a microelectronic device structure according to embodiments of the disclosure.

FIG. 25 is a simplified schematic block diagram illustrating an electronic system in accordance with embodiments of the disclosure.

### DETAILED DESCRIPTION

A microelectronic device (e.g., a memory device, a microelectronic device structure, an electronic signal processor device, a semiconductor device) that includes one or more interconnect structures individually electrically coupled to a respective feature (e.g., a data line) is disclosed. The microelectronic device may include multiple stacked decks, each deck comprising a stack structure of alternating tiers of a conductive material and an insulative material, with one or more interconnect structures formed from the conductive material of the tiers. A set of multiple interconnect structures within the stack structure may be configured as a vertical stack of interconnect structures separated from one another by the insulative material of the stack structure. A data line of a first deck may be electrically coupled to an interconnect structure of a second deck that is vertically offset from the first deck.

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. The description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessary limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one of the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “over,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Moreover, if a material is formed to cover a surface (e.g., a substantially vertical sidewall of a structure), the material may be referred to as being formed “over” the surface even though the material may not be spatially above the covered surface. Likewise, the surface may be referred to as being “under” the formed material. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, any ordinal terms, such as “first,” “second,” etc., is used for clarity and convenience in understanding the disclosure and accompanying drawings or to distinguish one claimed construct from another, and do not connote or depend on any specific sequence, preference, time, uniqueness, or order, except where the context clearly indicates otherwise.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be greater than or equal to 90.0 percent met, greater than or equal to 95.0 percent met, greater than or equal to 99.0 percent met, greater than or equal to 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative materials, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, “sacrificial material” means and includes one material that may be selectively removed relative to one or more other materials (e.g., one or more insulative materials). The sacrificial material may be selectively etchable relative to the one or more other materials during common (e.g., collective, mutual) exposure to a first etchant; and the one or more other materials may be selectively etchable to the sacrificial material during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. By way of non-limiting example, depending on the material composition of the one or more other materials, the sacrificial material may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓCy), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). The sacrificial material may, for example, be selectively etchable relative to the one or more other materials during common exposure to a wet etchant comprising phosphoric acid (H₃PO₄). In addition, a “sacrificial structure” means and includes a structure formed of and including sacrificial material.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

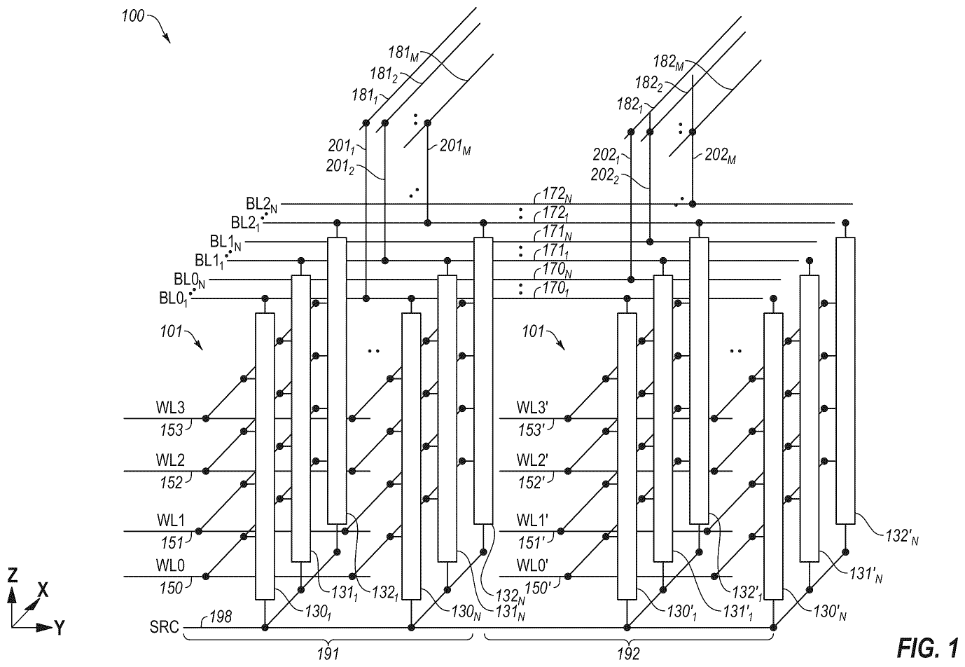

FIG. 1-FIG. 22B are various views (described in further detail below) illustrating a microelectronic device structure at different processing stages of a method of forming a microelectronic device (e.g., a memory device, such as a 3D NAND Flash memory device or a signal processor device, such as a microprocessor), in accordance with embodiments of the disclosure. With the description provided below, it will be readily apparent to one of ordinary skill in the art that the methods described herein may be used for forming various other devices. In other words, the methods of the disclosure may be used whenever it is desired to form a microelectronic device.

FIG. 1 is a simplified schematic diagram depicting a portion of a memory device 100 according to one embodiment of the disclosure. Various embodiments of the memory device 100 include a non-volatile (e.g., NAND flash memory device) or other types of memory devices. As shown in FIG. 1, the memory device 100 may include a memory cell area 101 (e.g., memory array area), a set of data lines 170₁ through 170_{N}, a set of data lines 171₁ through 171_{N}, a set of data lines 172₁ through 172_{N}, a set of interconnect structures 181₁ through 181_{M}, and a set of interconnect structures 182₁ through 182_{M}. Data lines 170₁ through 170₉, 171₁ through 171₉, and 172₁ through 172₉ may include (e.g., may be part of) bit lines (e.g., local bit lines) of the memory device 100.

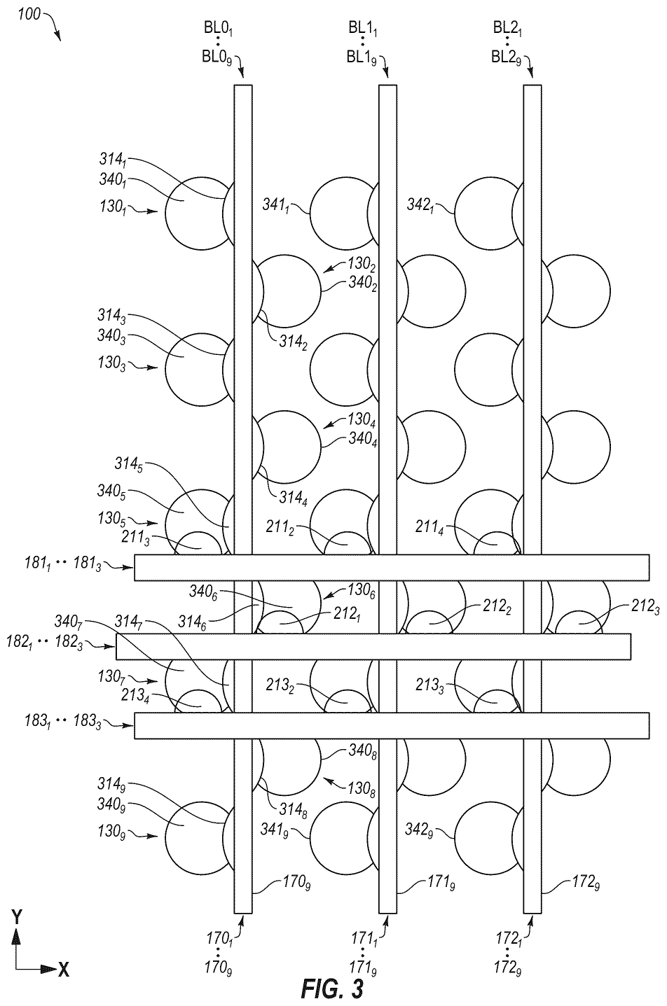

The memory device 100 may include an equal number of data lines per set among sets (e.g., stacks) of data lines 170₁ through 170_{N}, 171₁ through 171_{N}, and 172₁ through 172_{N}. In some embodiments, the memory device 100 includes varying numbers of data lines among the sets of data lines 170₁ through 170_{N}, 171₁ through 171_{N}, and 172₁ through 172_{N}. In FIG. 1 and FIG. 3, the label “N” (the number of data lines in an individual set of data lines) may be any integer greater than or equal to two (e.g., N may be equal to two (N=2) or N may be greater than two (N>2)).

As shown in FIG. 1, data lines 170₁ through 170_{N} may carry signals (e.g., bit line signals BL0₁ through BL0_{N}), respectively. Data lines 171₁ through 171_{N} may carry bit line signals BL1₁ through BL1_{N}, respectively. Data lines 172₁ through 172_{N} may carry bit line signals BL2₁ through BL2_{N}, respectively.

FIG. 1 shows directions X, Y, and Z that may be relative to the physical directions (e.g., dimensions) of the structure of the memory device 100. For example, the Z-direction may be a direction perpendicular to (e.g., vertical direction relative to) a substrate (e.g., a semiconductor substrate) surface of the memory device 100. The Z-direction is perpendicular to the X-direction and Y-direction (e.g., the Z-direction is perpendicular to an X-Y plane of the memory device 100).

In the memory device 100, data lines 170₁ through 170_{N}, data lines 171₁ through 171_{N}, and data lines 172₁ through 172_{N} may be configured as conductive lines and have respective lengths extending in the Y-direction. As described in more detail below, the data lines within the set of data lines 170₁ through 170_{N} may be formed in a stack structure. In such a stack structure, the data lines within the same set may be located (e.g., stacked) in different tiers in the Z-direction adjacent to the memory cell area 101 of the memory device 100. For example, in the memory device 100, data lines 170₁ through 170_{N}, data lines 171₁ through 171_{N}, and data lines 172₁ through 172_{N} may be formed in respective stacks (e.g., side-by-side stacks in the X-direction) adjacent to the memory cell area 101. For example, data lines 170₁ through 170_{N} may be formed in a first stack of data lines, data lines 171₁ through 171_{N} may be formed in a second stack of data lines next to the first stack, and data lines 172₁ through 172_{N} may be formed in a third stack of data lines next to the second stack.

As shown in FIG. 1, the memory device 100 includes sets of stacked interconnect structures 181₁ through 181_{M} and 182₁ through 182_{M}. The memory device 100 may include an equal number of interconnect structures per set among the sets (e.g., the stacks) of interconnect structures 181₁ through 181_{M} and 182₁ through 182_{M}. In some embodiments, the memory device 100 includes varying numbers of interconnect structures among the sets of the interconnect structures 181₁ through 181_{M} and 182₁ through 182_{M}. In FIG. 1, the label “M” (the number of interconnect structures in an individual set of interconnect structures) may be any integer greater than or equal to one (M may be equal to one (M=1) or M may be greater than one (M>1)).

In the memory device 100, interconnect structures 181₁ through 181_{M} and interconnect structures 182₁ through 182_{M} may be configured as conductive lines and have respective lengths extending in the X-direction or as conductive plates of the memory device 100 and have respective lengths in the X-direction and/or the Y-direction. In other embodiments of the disclosure, interconnect structures 181₁ through 181_{M} or interconnect structures 182₁ through 182_{M} have respective lengths extending in other directions. In one example, interconnect structures 181₁ through 181_{M} or interconnect structures 182₁ through 182_{M} have respective lengths extending in the Y-direction. In another example, interconnect structures 181₁ through 181_{M} or interconnect structures 182₁ through 182_{M} have respective lengths extending in a direction that equally bisects the X-direction and the Y-direction. In other words, the interconnect structures 181₁ through 181_{M} or interconnect structures 182₁ through 182_{M} have lengths extending in a direction oriented approximately forty-five degrees (45°) from that of data lines 170₁ through 170_{N}, data lines 171₁ through 171_{N}, and/or data lines 172₁ through 172_{N}. In other examples, interconnect structures 181₁ through 181_{M} or interconnect structures 182₁ through 182_{M} have respective lengths extending in various other directions between the X-direction and the Y-direction.

As described in more detail below, the interconnect structures 181₁ through 181_{M} may be formed in a stack structure. In such a stack structure, the interconnect structures within the same set may be located (e.g., stacked) in different tiers in the Z-direction over the memory cell area 101 and adjacent to data lines 170₁ through 170_{N}, data lines 171₁ through 171_{N}, and data lines 172₁ through 172_{N} of the memory device 100. For example, in the memory device 100, interconnect structures 181₁ through 181_{M} and interconnect structures 182₁ through 182_{M} may be formed in respective stacks (e.g., side-by-side stacks in the Y-direction) adjacent to the memory cell area 101 and adjacent to data lines 170₁ through 170_{N}, data lines 171₁ through 171_{N}, and data lines 172₁ through 172_{N}. For example, interconnect structures 181₁ through 181_{M} may be formed in a stack (e.g., first stack of interconnect structures) and interconnect structures 182₁ through 182_{M} may be formed in another stack (e.g., a second stack of interconnect structures adjacent to the first stack). In embodiments having greater than or equal to three sets of stacked interconnect structures, interconnect structures 1831 through 183_{M} (as depicted in FIG. 3) may be formed in another stack (e.g., a third stack of interconnect structures next to the second stack).

Individual interconnect structures 181₁ through 181_{M} or 182₁ through 182_{M} are electrically coupled to one or more data lines 170₁ through 170_{N}, 171₁ through 171_{N}, or 172₁ through 172_{N} by respective conductive structures 201₁ through 201_{M} or respective conductive structures 202₁ through 202_{M} to carry bit line signals BL0₁ through BL0_{N}, BL1₁ through BL1_{N}, or BL2₁ through BL2_{N}. Conductive structures 201₁ through 201_{M} or 202₁ through 202_{M} of the memory device 100 may include (e.g., may be formed from) a conductive material (e.g., metal, conductively doped polysilicon, other conductive materials, or combinations thereof). The conductive structures 201₁ through 201_{M} and conductive structures 202₁ through 202_{M} may have a structure (e.g., vertical structure) of material that extends in the Z-direction between one or more corresponding data lines 170₁ through 170_{N}, 171₁ through 171_{N}, or 172₁ through 172_{N} and one or more corresponding interconnect structures 181₁ through 181_{M} and interconnect structures 182₁ through 182_{M}. The conductive structures 201₁ through 201_{M} and conductive structures 202₁ through 202_{M} may be electrically coupled to (e.g., may contact) one or more data lines 170₁ through 170_{N}, data lines 171₁ through 171_{N}, and data lines 172₁ through 172_{N} and to one or more of the interconnect structures 181₁ through 181_{M} and interconnect structures 182₁ through 182_{M} and electrically separated from (e.g., not contact with) the data lines 170₁ through 170_{N}, data lines 171₁ through 171_{N}, and data lines 172₁ through 172_{N} and from the other interconnect structures 181₁ through 181_{M} and interconnect structures 182₁ through 182_{M}.

Since the stacks of interconnect structures 181₁ through 181_{M} and 182₁ through 182_{M} extend in the X-directions, and since the data lines 170₁ through 170_{N}, data lines 171₁ through 171_{N}, and data lines 172₁ through 172_{N} extend in the Y-direction, an individual stack of interconnect structures may transversely overlie portions of one, multiple, or all stacks of the data lines, the stacks of interconnect structures being above the stacks of data lines in the Z-direction.

FIG. 1 shows the memory device 100 including three sets of data lines 170₁ through 170_{N}, 171₁ through 171_{N}, and 172₁ through 172_{N} and two sets of interconnect structures 181₁ through 181_{M} and 182₁ through 182_{M}. However, the memory device 100 may include numerous sets of data lines and/or numerous sets of interconnect structures.

As shown in FIG. 1, memory cell area 101 is organized into blocks (blocks of memory cells). FIG. 1 shows the memory device 100 including two blocks 191 and 192 as an example. However, the memory device 100 may include numerous blocks. The blocks (e.g., blocks 191 and 192) of the memory device 100 may share data lines (e.g., data lines 170₁ through 170_{N}, data lines 171₁ through 171_{N}, and data lines 172₁ through 172_{N}) to carry information (in the form of signals) read from or to be stored in memory cells of selected memory cells (e.g., selected memory cells in block 191 or 192) of the memory device 100.

As shown in FIG. 1, the memory device 100 includes respective memory cell strings in individual blocks (e.g., blocks 191 and 192). For example, in block 191, the memory device 100 includes memory cell strings 130₁ through 130_{N}, memory cell strings 131₁ through 131_{N}, and memory cell strings 132₁ through 132_{N} and in block 192, the memory device 100 includes memory cell strings 130′1 through 130′_{N}, memory cell strings 131′₁ through 131′_{N}, and memory cell strings 132′₁ through 132′_{N}.

In individual blocks 191 or 192 of the memory device 100, the number of memory cell strings in the X-direction that are electrically coupled to a set of data lines may be equal to the number (e.g., N) of data lines of the set of data lines. Further, in individual blocks 191 or 192 of the memory device 100, the number (e.g., M) of interconnect structures 181₁ through 181_{M} in a set may be equal to the number of sets of data lines in that block of the memory device 100. Likewise, the number of sets of interconnect structures in individual blocks 191 or 192 of the memory device 100 may be equal to the number (e.g., N) of data lines of one or more of the sets of data lines in that block of the memory device 100.

Individual memory cell strings 130₁ of the memory device 100 may have series-connected memory cells (e.g., four series-connected memory cells). The memory cells may be formed (e.g., formed vertically) in different elevations in the Z-direction of the memory device 100 and under the stack structures of data lines 170₁ through 170_{N}, 171₁ through 171_{N}, and 172₁ through 172_{N}. In embodiments of the disclosure, the quantity of memory cells in an individual memory cell string of the memory device 100 may vary.

As shown in FIG. 1, the memory device 100 may include control gates 150, 151, 152, and 153 that may respectively carry corresponding signals WL0, WL1, WL2, and WL3. Control gates 150, 151, 152, and 153 may include (or may be part of) access lines (e.g., word lines) of the memory device 100. Individual control gates 150, 151, 152, and 153 may be part of a conductive material located in a single tier of the memory device 100.

The memory device 100 may use signals WL0, WL1, WL2, and WL3 to control access to memory cells within memory cell strings 130₁ through 130_{N}, within memory cell strings 131₁ through 131_{N}, or within memory cell strings 132₁ through 132_{N} of block 191 during an operation (e.g., read, write, or erase operation). For example, during a read operation, the memory device 100 may use signals WL0, WL1, WL2, and WL3 to control access to memory cells of block 191 to read (e.g., sense) information (e.g., previously stored information) from memory cells of block 191. In another example, during a write operation, the memory device 100 may use signals WL0, WL1, WL2, and WL3 to control access to memory cells of block 191 to store information therein.

The memory device 100 may include similar control gates in block 192. For example, memory device may include control gates 150′, 151′, 152′, and 153′ that may respectively carry corresponding signals WL0′, WL1′, WL2′, and WL3′. Individual control gates 150′, 151′, 152′, and 153′ may be part of a structure of a conductive material located in a single elevation of the memory device 100. Control gates 150′, 151′, 152′, and 153′ may be located in the same elevations as control gates 150, 151, 152, and 153, respectively. As shown in FIG. 1, control gates 150′, 151′, 152′, and 153′ may be electrically separated from control gates 150, 151, 152, and 153. Thus, the access lines that include control gates 150, 151, 152, and 153 may be electrically separated from the access lines that include control gates control gates 150′, 151′, 152′, and 153′.

The memory device 100 may use signals WL0′, WL1′, WL2′, and WL3′ to control access to memory cells within memory cell strings 130′1 through 130′_{N}, within memory cell strings 131′1 through 131′_{N}, or within memory cell strings 132′₁ through 132′_{N} of block 192 during a read, write, or erase operation. For example, during a read operation, the memory device 100 may use signals WL0′, WL1′, WL2′, and WL3′ to control access to memory cells of block 192 to read information from memory cells of block 192. In another example, during a write operation, the memory device 100 may use signals WL0′, WL1′, WL2′, and WL3′ to control access to memory cells of block 192 to store information in memory cells of block 192.

FIG. 1 shows control gates 150, 151, 152, and 153 in the block 191 of the memory device 100. The quantity of control gates in individual blocks of the memory device 100 may vary (e.g., may be more than four).

As shown in FIG. 1, the memory device 100 includes a source line 198 (e.g., a source plate) that may carry a signal (e.g., a source line signal) SRC. The line 198 may be configured as a conductive line or a conductive plate of the memory device 100. Line 198 may be common conductive line (e.g., a common source line or a common source plate) of block 191 and 192. Line 198 may be coupled to a ground connection of the memory device 100.

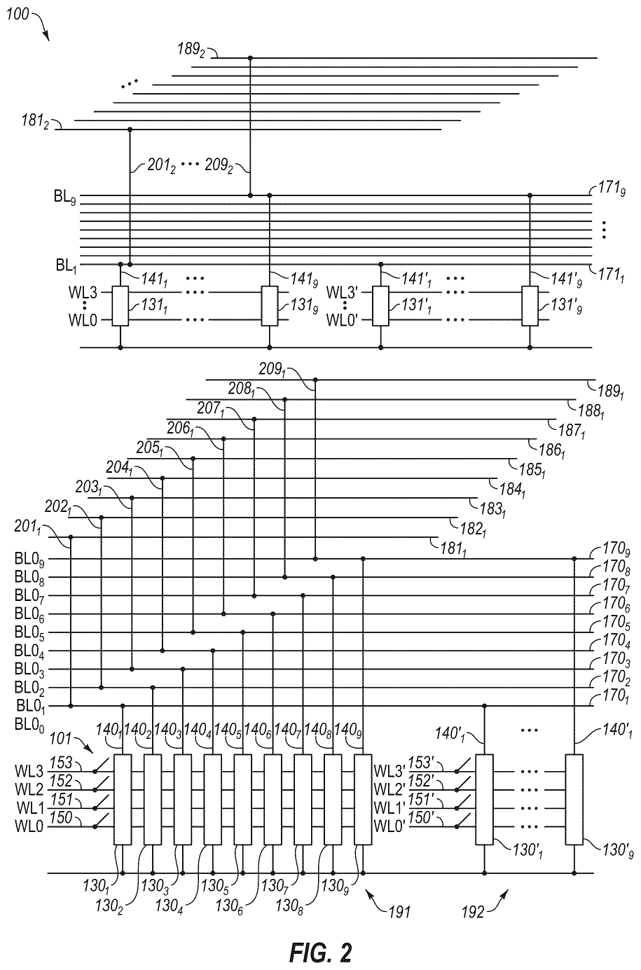

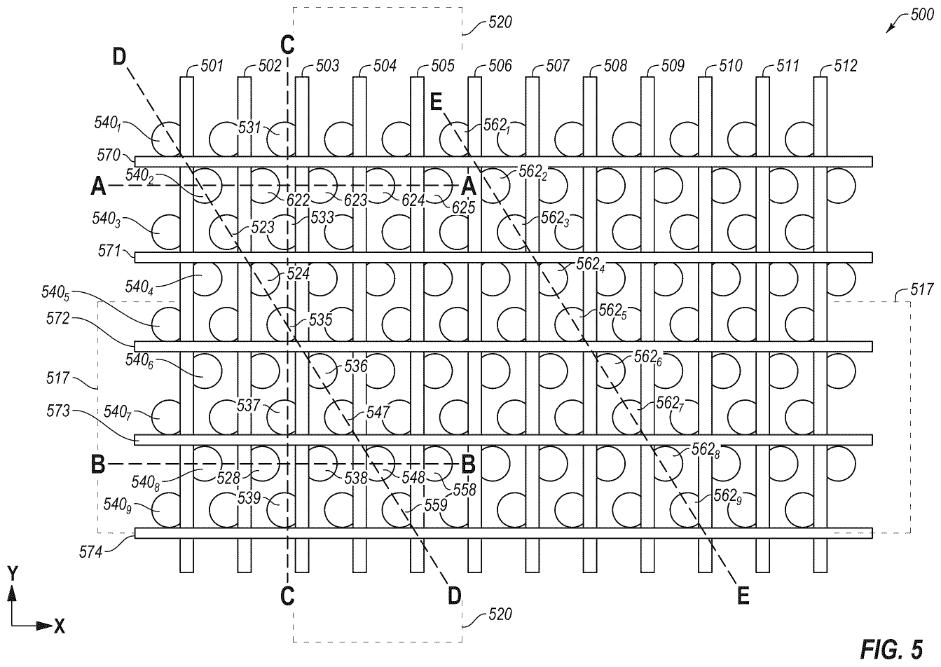

The memory device 100 may include other features (e.g., components), which are not shown in FIG. 1 so as not to obscure the embodiments described herein. Aspects of the memory device 100 are described below with reference to FIG. 2 through FIG. 4. At least a portion of the memory cell area 101, the sets of data lines 170₁ through 170_{N}, 171₁ through 171_{N}, and 172₁ through 172_{N}, the sets of interconnect structures 181₁ through 181_{M} and 182₁ through 182_{M}, or the conductive structures 201₁ through 201_{M} and 202₁ through 202_{M} of the memory device 100 may include features that may be similar to (or the same as) any of the memory devices described below with reference to FIG. 5 through FIG. 25.

FIG. 2 shows a schematic diagram of a portion of the memory device 100 of FIG. 1 including an embodiment wherein the memory device 100 includes nine data lines (e.g., N=9) in individual sets of data lines and two interconnect structures in individual sets of interconnect structures (e.g., M=2), according to embodiments of the invention. Similar or identical elements between FIG. 1 and FIG. 2 are given the same labels and reference numerals. As shown in FIG. 2, the memory device 100 may include a set of nine data lines 170₁ through 170₉, a set of nine data lines 171₁ through 171₉, and nine sets of interconnect structures, individual sets of interconnect structures having two interconnect structures 181₁ and 181₂. Following the description above with respect to FIG. 1, the quantity (e.g., 9) of sets of interconnect structures corresponds to the quantity (e.g., N=9) of data lines in an individual set of data lines. Likewise, the quantity (e.g., M=2) of interconnect structures in an individual set of interconnect structures corresponds to the quantity (e.g., 2) of sets of data lines. However, in other embodiments of the disclosure, there is no correlation between the respective quantities of data lines and sets of interconnect structures and/or the respective quantities of sets of data lines and interconnect structures.

As depicted in FIG. 2, the memory device 100 may include interconnect structures 181₁ through 189₁ and interconnect structures 181₂ through 189₂ that are coupled to a respective set of data lines. For example, in block 191, the memory device 100 may include nine data lines 170₁ through 170₉ coupled to nine respective interconnect structures 181₁ through 189₁. Similarly, in block 192, the memory device 100 may include nine data lines 171₁ through 171₉ coupled to nine respective interconnect structures 181₂ through 189₂.

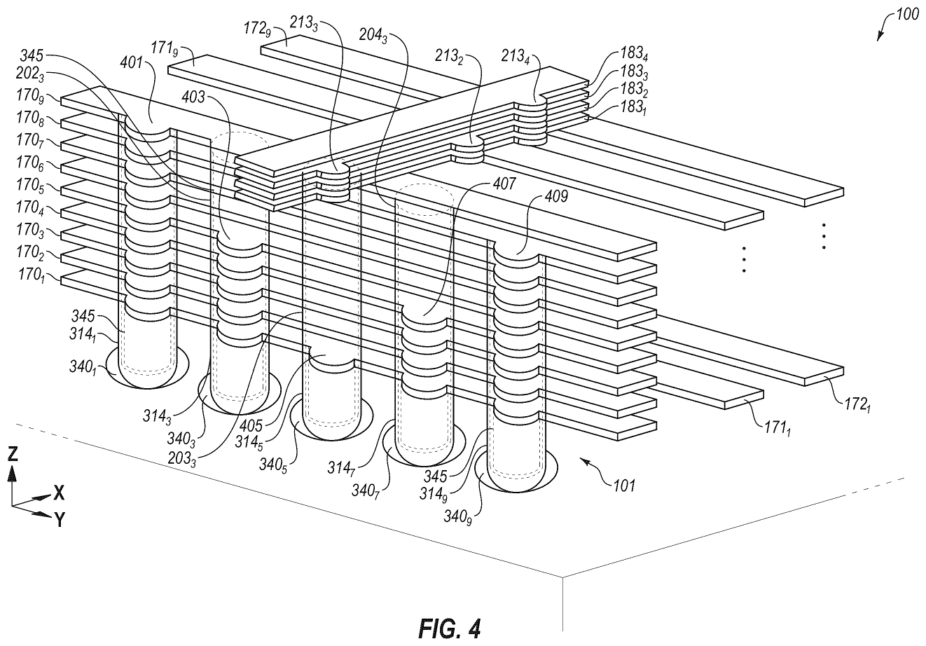

For the purposes of simplicity and clarity, interconnect structures 181₁ through 189₁ and 181₂ through 189₂ are not depicted in FIG. 2 in stacked configurations, nor grouped as respective sets of interconnect structures. However, in various embodiments of the memory device 100, individual sets of interconnect structures 181₁ and 181₂, 182₁ and 182₂, 183₁ and 183₂, etc., may be arranged in a stacked configuration as depicted in FIG. 1 and FIG. 4.

As described above with respect to FIG. 1, data lines 170₁ through 170₉ may be coupled to corresponding interconnect structures 181₁ through 189₁ via conductive structures 201₁ through 209₁. Likewise, data lines 171₁ through 171₉ may be coupled to corresponding interconnect structures 181₂ through 189₂ via conductive structures 201₂ through 209₂.

As described above with respect to FIG. 1, the quantity of memory cell strings 130₁ through 130₉, 130′₁ through 130′₉, 131₁ through 131₉, 131′₁ through 131′₉ that are coupled to a set of data lines may be equal to the quantity (e.g., N) of data lines of the set of data lines. Thus, as depicted in FIG. 2, individual blocks 191 and 192 may include nine memory cell strings that are coupled to a respective set of data lines. For example, in block 191, the memory device 100 may include nine memory cell strings 130₁ through 130₉ coupled to data lines 170₁ through 170₉, respectively; and nine memory cell strings 131₁ through 131₉ coupled to data lines 171₁ through 171₉. Similarly, in block 192, the memory device 100 may include nine memory cell strings 130′₁ through 130′₉ coupled to data lines 170₁ through 170₉, respectively; and nine memory cell strings 131′₁ through 131′₉ coupled to data lines 171₁ through 171₉, respectively.

As shown in FIG. 2, memory cell strings 130₁ through 130₉ may be coupled to data lines 170₁ through 170₉ through conductive connections 140₁ through 140₉, respectively. Memory cell strings 130′₁ through 130′₉ may be coupled to data lines 170₁ through 170₉ through conductive connections 140′₁ through 140′₉, respectively. Similarly, memory cell strings 131₁ through 131₉ may be coupled to data lines 171₁ through 171₉ through conductive connections 1411 through 141₉, respectively. Memory cell strings 131′₁ through 131′₉ may be coupled to data lines 171₁ through 171₉ through conductive connections 14l′₁ through 141′₉, respectively.

As shown in FIG. 2, memory cell strings 130₁ through 130₉ in block 191 may be coupled (e.g., coupled in a sequential order) to data lines 170₁ through 170₉ similarly to how memory cell strings 130′₁ through 130′₉ in block 192 are coupled to data lines 170₁ through 170₉. As such, conductive connections 140₁ through 140₉ may have similar (or the same) structures as conductive connections 140′₁ through 140′₉.

FIG. 3 is a simplified top view of the memory device 100 including data lines 170₁ through 170₉, data lines 171₁ through 171₉, data lines 172₁ through 172₉, conductive contacts 340₁ through 340₉ (e.g., drain contacts), conductive contacts 341₁ through 341₉ (of which only conductive contacts 341₁ and 341₉ are labeled in FIG. 3), conductive contacts 342₁ through 342₉, (of which only conductive contacts 342₁ and 342₉ are labeled in FIG. 3) conductive structures 314₁ through 314₉, set of interconnect structures 181₁ through 181_{M}, set of interconnect structures 182₁ through 182_{M}, and set of interconnect structures 1831 through 183_{M} of the memory device 100, according to some embodiments described herein.

The memory cell strings 130₁ through 130_{N}, memory cell strings 131₁ through 131_{N}, and memory cell strings 132₁ through 132_{N} comprise respective conductive contacts 340₁ through 340_{N}, conductive contacts 341₁ through 341_{N}, and conductive contacts 342₁ through 342_{N}. The conductive contacts 340₁ through 340_{N}, 341₁ through 341_{N}, and 342₁ through 342_{N} may include (e.g., may be formed from) a conductive material (e.g., metal, conductively doped polysilicon, other conductive materials, or combinations thereof). The conductive contacts 340₁ through 340_{N}, 341₁ through 341_{N}, or 342₁ through 342_{N} may function as respective drain contacts of memory cell strings 130₁ through 130_{N}, 131₁ through 131_{N}, or 132₁ through 132_{N}. In embodiments of the memory device 100, the shape (e.g., in the top view as depicted in FIG. 3) of the conductive contacts 340₁ through 340_{N}, 341₁ through 341_{N}, and 342₁ through 342_{N} may be substantially circular. The shape (e.g., in the top view as depicted in FIG. 3) of the conductive contacts 340₁ through 340_{N}, 341₁ through 341_{N}, and 342₁ through 342_{N} may be similar to the shape (e.g., circular) of an individual conductive contact's respective memory cell string 130₁ through 130_{N}, 131₁ through 131_{N}, or 132₁ through 132_{N}.

Still referring to FIG. 3, conductive contacts 340₁ through 340₉, 341₁ through 341₉, and 342₁ through 342₉ are located below (e.g., under) (in the Z-direction) respective stacks of data lines 170₁ through 170₉, 171₁ through 171₉, and 172₁ through 172₉. As shown in FIG. 3, the data lines 170₁ through 170₉, 171₁ through 171₉, and 172₁ through 172₉ have lengths extending in the Y-direction.

Conductive contacts 340₁ through 340₉ may be located along the lengths (in the Y-direction) and on both sides (in the X-direction) of the stack of data lines 170₁ through 170₉. Similarly, conductive contacts 341₁ through 341₉ may be located along the lengths (in the Y-direction) and on both sides (in the X-direction) of the stack of data lines 171₁ through 171₉. Conductive contacts 342₁ through 342₉ may be located along the lengths (in the Y-direction) and on both sides (in the X-direction) of the stack of data lines 172₁ through 172₉.

Individual conductive structures 314₁ through 314₉ of the memory device 100 may overlap (with respect to the top view) and contact (e.g., electrically couple to) a respective conductive contact 3401 through 340₉, 341₁ through 341₉, or 342₁ through 342₉. For example, conductive structure 314₁ may overlap and contact conductive contact 340₁, conductive structure 314₂ may overlap and contact conductive contact 340₂, and so on. Conductive structures 314₁ through 314₉ may be alternatively formed on the sides (e.g., in the X-direction) of the stack of data lines 170₁ through 170₉.

As shown in FIG. 3 and FIG. 4, individual conductive structures 314₁ through 314₉ may also contact (e.g., electrically couple to) a respective data line 170₁ through 170₉ of a stack of data lines at landing pads 401, 403, 405, 407, 409 of the respective data line. For example, conductive structure 340₁ may contact data line 170₉ at the landing pad 401 (shown in FIG. 4), which may be an integral part of data line 170₉, and conductive structure 314₃ may contact data line 170₅ at the landing pad 403 of data line 170₅.

In the memory device 100, conductive structures 314₁ through 314₉ may be part of one corresponding conductive connections 140₁ through 140₉ (depicted in FIG. 2). Conductive structures 314₁ through 314₉ may include (e.g., may be formed from) a conductive material (e.g., metal, conductively doped polysilicon, other conductive materials, or combinations thereof). Conductive structure 314 may extend vertically (e.g., in the Z-direction).

As described above with reference to FIG. 1 and FIG. 2, interconnect structures 181₁ through 181_{M} may be electrically coupled to respective conductive structures 201₁ through 201_{M}. Referring now to FIG. 3, individual conductive structures 201₁ through 201_{M} depicted in FIG. 1 and FIG. 2 may contact (e.g., electrically couple to) a respective interconnect structure 181₁ through 181_{M} of a stack of interconnect structures at a respective landing pad 211₂ through 211₄ (e.g., a landing pad directly above, in the Z-direction, a portion of a respective conductive structure 201₁ through 201_{M} from a top view) of the respective interconnect structure 181₁ through 181_{M}. For example, as depicted in FIG. 4, the conductive structure 203₃ may contact interconnect structure 183₃ at a landing pad 213₃ (that may be an integral part) of the interconnect structure 183₃.

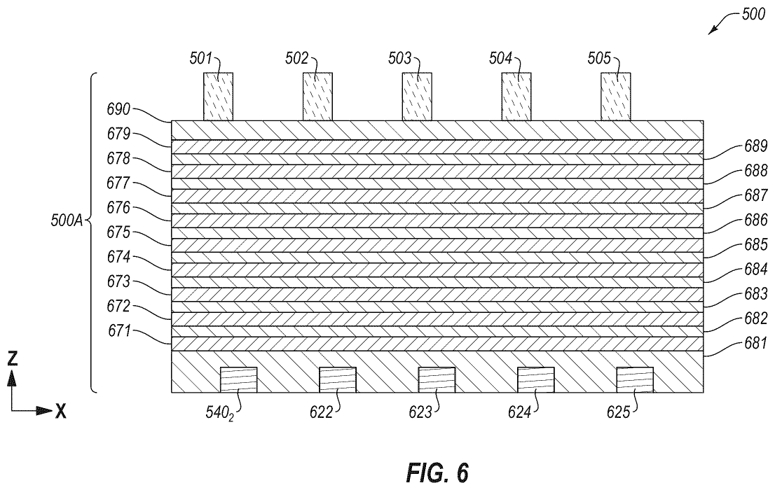

Referring to FIG. 3, in the memory device 100, one or more landing pads 211₂ through 211₄, 212₁ through 212₃, or 213₂ through 213₄ comprise an electrically conductive coupling to structures on a lower (e.g., in the Z-direction) deck 500A (FIG. 6) of the memory device 100.

As described above with reference to FIG. 2 and FIG. 3, the memory device 100 may have, for example, nine data lines (e.g., N=9) in an individual set of data lines. As shown in FIG. 3, the set of data lines 170₁ through 170₉ (having associated signals BL0₁ through BL0₉) may be formed in a stack of nine data lines that are stacked in the Z-direction. For example, as shown in FIG. 4, data line 170₉ may be the topmost data line, and data lines 170₁ through 170₈ (which are not shown under data line 170₉ in FIG. 3) may be adjacent to (e.g., vertically adjacent to, under) (below in the Z-direction) data line 170₉.

Similarly, the set of data lines 171₁ through 171₉ (having associated signals BL1₁ through BL1₉) may be formed in a stack of nine data lines that are stacked in the Z-direction. For example, as shown in FIG. 4, data line 171₉ may be the topmost data line, and data lines 171₂ through 171₈ (which are not shown) may be under (below in the Z-direction) data line 171₉.

The set of data lines 172₁ through 172₉ (having associated signals BL2₁ through BL2₉) may be formed in a stack of nine data lines that are stacked in the Z-direction. For example, as shown in FIG. 4, data line 172₉ may be the topmost data line, and data lines 172₂ through 172₈ (which are not shown under data line 172₉) may be under (below in the Z-direction) data line 172₉.

Embodiments of the memory device 100 have, in reference to FIG. 2, nine sets of interconnect structures, with two interconnect structures in an individual set (e.g., M=2). As shown in FIG. 3, the memory device 100 has three interconnect structures in an individual set (e.g., M=3). Embodiments of the memory device 100 similar to the depiction in FIG. 3 comprise nine sets of interconnect structures, corresponding to the quantity of data lines in an individual set of data lines (e.g., N=9).

FIG. 3 depicts a partial representation of such embodiments for purposes of clarity and simplicity; thus, only three sets of interconnect structures 181₁ through 181₃, 182₁ through 182₃, and 183₁ through 183₃ and only three sets of data lines 170₁ through 170₉, 171₁ through 171₉, and 172₁ through 172₉ are depicted. However, other embodiments of the disclosure include greater or lesser quantities of sets of interconnect structures and/or sets of data lines.

FIG. 3 shows that interconnect structures 181₁ through 181₃ may be formed in a stack of interconnect structures that are stacked in the Z-direction. For example, interconnect structure 181₃ may be the uppermost interconnect structure, and interconnect structures 181₁ through 181₂ (which are not shown under interconnect structure 181₃ in FIG. 3) may be under (below in the Z-direction) interconnect structure 181₃.

Similarly, the set of interconnect structures 182₁ through 182₃ may be formed in a stack of interconnect structures that are stacked in the Z-direction. As shown in FIG. 4, interconnect structure 183₄ may be the topmost interconnect structure, and interconnect structures 183₁ through 183₃ may be under (below in the Z-direction) interconnect structure 183₄.

For the purpose of simplicity, detailed description of any particular element may not be repeated from one figure to the next. Some elements of the memory device 100 and other microelectronic devices (e.g., the microelectronic device structure 500) described herein may be omitted from a particular figure of the drawings so as to not obscure the element (or elements) being described in that particular figure. The dimensions (e.g., physical structures) of the elements shown in the drawings described herein are not necessarily drawn to scale.

FIG. 4 shows an isometric view of portion of the memory device 100, including memory cell area 101 and stacks of data lines 170₁ through 170₉, 171₁ through 171₉, and 172₁ through 172₉ and stack of interconnect structures 183₁ through 183₄, according to some embodiments described herein. As shown in FIG. 4, the set of data lines 170₁ through 170₉ may be formed in a stack of nine data lines. The set of data lines 171₁ through 171₉ may be formed in another stack of nine data lines next to the stack of data lines 170₁ through 170₉. The set of data lines 172₁ through 172₉ may be formed in another stack of nine data lines next to the stack of data lines 171₁ through 171₉. The stacks of data lines 170₁ through 170₉, 171₁ through 171₉, and 172₁ through 172₉ may be located adjacent to each other (in the X-direction) and located on the same elevation of the memory device 100. The data lines 170₁ through 170₉, 171₁ through 171₉, and 172₁ through 172₉ may horizontally extend in the Y-direction, while the interconnect structures 183₁ through 183₄ horizontally extend substantially perpendicular to the data lines 170₁ through 170₉, 171₁ through 171₉, and 172₁ through 172₉ (e.g., in the X-direction). In other embodiments, the interconnect structures 183₁ through 183₄ horizontally extend substantially parallel (e.g., in substantially the same horizontal direction) to the data lines 170₁ through 170₉, 171₁ through 171₉, and 172₁ through 172₉. In yet other embodiments, the interconnect structures 183₁ through 183₄ horizontally extend in directions neither parallel nor perpendicular to the data lines 170₁ through 170₉, 171₁ through 171₉, and 172₁ through 172₉.

Individual data lines 170₁ through 170₉ may include (e.g., may be formed from) a conductive material. Thus, the set of data lines 170₁ through 170₉ may include nine stacked discrete (e.g., separate) materials adjacent to memory cell area 101. Similarly, the set of data lines 171₁ through 171₉ may be formed in another stack of nine tiers of conductive materials next to the stack of data lines 170₁ through 170₉. The set of data lines 172₁ through 172₉ may be formed in another stack of nine tiers of conductive materials next to the stack of data lines 171₁ through 171₉. Example materials for data lines 170₁ through 170₉, 171₁ through 171₉, and 172₁ through 172₉ include metal, conductively doped polysilicon, other conductive materials, or combinations thereof.

FIG. 4 also shows some of the conductive contacts 340₁, 340₃, 340₅, 340₇, and 340₉ and corresponding conductive structures 314₁, 314₃, 314₅, 314₇, and 314₉ of the memory device 100. Conductive structures 314₁, 314₃, 314₅, 314₇, and 314₉ may be parts of conductive connections 140₁, 140₃, 140₅, 140₇, 140₉ (shown in FIG. 2), respectively, of the memory device 100. For simplicity and clarity, FIG. 4 omits other conductive contacts 340₂, 340₄, 340₆, 340₈, 341₁ through 341₉, and 342₁ through 342₉, (shown in FIG. 3) and corresponding conductive structures coupled to the conductive contacts of the memory device 100.

As shown in FIG. 4, conductive structures 314₁, 314₃, 314₅, 314₇, and 314₉ are coupled to respective data lines 170₉, 170₅, 170₁, 170₄, and 170₈ at landing pads 401, 403, 405, 407, and 409, respectively. Landing pads 401, 403, 405, 407, or 409 may be parts (e.g., integral parts) of data lines 170₉, 170₅, 170₁, 170₄, and 170₈, respectively. Thus, the material composition of landing pads 401, 403, 405, 407, or 409 may be the same as the material composition of data lines 170₉, 170₅, 170₁, 170₄, and 170₈, respectively. In FIG. 4, an individual landing pad 401, 403, 405, 407, or 409 may extend from a side of the respective data line 170₉, 170₅, 170₁, 170₄, and 170₈ in a direction (e.g., the X-direction) perpendicular to the length of the respective data line 170₉, 170₅, 170₁, 170₄, and 170₈.

As shown in FIG. 4, individual interconnect structures 183₁ through 183₄ may include (e.g., may be formed from) a tier of conductive material. Thus, the set of interconnect structures 183₁ through 183₄ may include four stacked discrete (e.g., separate) materials adjacent to the memory cell area 101 and adjacent to the stacks of data lines 170₁ through 170₉, 171₁ through 171₉, and 172₁ through 172₉. For simplicity and clarity, FIG. 4 omits interconnect structures 181₁ through 181_{M}, interconnect structures 182₁ through 182_{M}, and interconnect structures 1835 through 183_{M}, shown in FIG. 1 through FIG. 3 and corresponding landing pads 211₁ through 211_{M}, landing pads 212₁ through 212M, landing pad 213₁, and landing pads 2135 through 213M. Similarly, the omitted sets of interconnect structures 181₁ through 181_{M} and 182₁ through 182_{M} may be formed in other tiers of conductive materials adjacent to the stack of interconnect structures 183₁ through 183₄. The set of interconnect structures 182₁ through 182_{M} may be formed in other tiers of conductive materials adjacent to the stack of interconnect structures 183₁ through 183₄. The set of interconnect structures 181₁ through 181_{M} may be formed in other tiers of conductive materials adjacent to the stack of interconnect structures 182₁ through 182_{M}. Additional sets of interconnect structures (e.g., 184₁ through 184_{M}, 185₁ through 185_{M}) may be formed in other tiers of conductive materials adjacent to the stack of interconnect structures 183₁ through 183₄ and beyond. Example materials for interconnect structures 181₁ through 181_{M}, interconnect structures 182₁ through 182_{M}, and interconnect structures 183₁ through 183_{M} include metal, conductively doped polysilicon, other conductive materials, or combinations thereof.

FIG. 4 only shows some of the conductive contacts 340₁, 340₃, 340₅, 340₇, and 340₉ and corresponding conductive structures 314₁, 314₃, 314₅, 314₇, and 314₉ of the memory device 100. Conductive structures 314₁, 314₃, 314₅, 314₇, and 314₉ may be parts of conductive connections 140₁, 140₃, 140₅, 140₇, 140₉ (shown in FIG. 2), respectively, of the memory device 100.

FIG. 4 depicts conductive structures 202₃, 203₃ and 204₃ of the memory device 100. For simplicity and clarity, other conductive structures 201₁ through 201_{M}, 202₁, 202₂, 202₄ through 202_{M}, 203₁, 203₂, 203₄ through 203_{M}, 204₁, 204₂, 204₄ through 204_{M}, 205₁ through 205_{M}, 206₁ through 206_{M}, 207₁ through 207_{M}, 208₁ through 208_{M}, and 209₁ through 209_{M} are omitted. As shown in FIG. 2, conductive structures 201₁ through 201_{M}, 202₁ through 202_{M}, etc., may be coupled to respective interconnect structures 181₁ through 181_{M}, 182₁ through 182_{M}, etc., at landing pads 2111 through 211_{M}, 212₁ through 212_{M}, etc., (shown in FIG. 3 and FIG. 4). Landing pads 211₁ through 211_{M}, 212₁ through 212_{M}, etc., may be parts (e.g., integral parts) of interconnect structures 181₁ through 181_{M}, 182₁ through 182_{M}, etc., respectively. Thus, the materials of landing pads 211₁ through 211_{M}, 212₁ through 212_{M}, etc., may be the same as the materials of interconnect structures 181₁ through 181_{M}, 182₁ through 182_{M}, etc., respectively. In FIG. 4, an individual landing pad 213₂, 213₃, and 213₄ may be a portion of a respective interconnect structure 183₁, 183₂, 183₃, or 183₄ in which the landing pad 213₂, 213₃, and 213₄ may protrude from a side of the respective interconnect structure 183₁, 183₂, 183₃, or 183₄ in a direction (e.g., the Y-direction) perpendicular to the length of the respective interconnect structure 183₁, 183₂, 183₃, or 183₄.

FIG. 4 depicts that the landing pad 213₃ of interconnect structure 183₃ vertically (e.g., in the Z-direction) overlies respective conductive contact 340₅. However, in other embodiments of the disclosure, landing pads 211₁ through 211_{M}, 212₁ through 212_{M}, etc., of interconnect structures 181₁ through 181_{M}, 182₁ through 182_{M}, etc., do not vertically overlie their respective conductive contact 340₁ through 340₉. Instead, an interconnect structure 181₁ through 181_{M}, 182₁ through 182_{M}, etc., may be electrically coupled to a data line 170₁ through 170₉, 171₁ through 171₉, etc., which, in turn, is coupled to a corresponding conductive contact 340₁ through 340₉ elsewhere along the length (e.g., in the Y-direction) of the data line; for example the data line is coupled to its corresponding conductive contact via a conductive structure 314₁, 314₃, 314₅, 314₇, or 314₉ of the data line that does not underlie the landing pad 211₁ through 211_{M}, 212₁ through 212_{M}, etc., of the interconnect structure.

As shown in FIG. 4, the memory device 100 may include spacers (e.g., dielectric spacers) 345, shown in dashed lines. Spacers 345 may electrically separate a respective conductive structure among conductive structures 314₁, 314₃, 314₅, 314₇, and 314₉ from the stack of data lines 170₁ through 170₉ and/or that electrically separate a respective conductive structure among conductive structures 202₃, 203₃, and 204₃ from a respective stack of interconnect structures among interconnect structures 181₁ through 181₄.

As described above with reference to FIG. 1-FIG. 4, the data lines 170₁ through 170₉ may be shared among the blocks 191 and 192 (FIG. 1 and FIG. 2). Similarly, the interconnect structures 181₁ through 181_{M} may be shared among the blocks 191, 192. Thus, the stacks of data lines 170₁ through 170₉ in FIG. 4 may extend adjacent to (e.g., formed to overlie) the blocks of the memory device 100 and may be coupled to respective conductive contacts (e.g., drain contacts) of respective memory cell strings in individual blocks 191, 192. Further, the stacks of interconnect structures 183₁ through 183₄ in FIG. 4 may extend adjacent to the blocks of the memory device 100 and may be coupled to respective conductive structures 201₁ through 201_{M}, conductive structures 202₁ through 202_{M}, conductive structures 2031 through 203M, etc., in individual blocks 191, 192.

The memory device 100 may include circuitry located adjacent to (e.g., under) memory cell area 101. Such circuitry may include circuit elements (e.g., transistors) coupled to other circuit elements (e.g., electrically coupled to data lines 170₁ through 170₉) of the memory device 100. The circuit elements of such circuitry may be configured to perform part of a function of the memory device 100. For example, the circuitry may include decoder circuits, driver circuits, buffers, sense amplifiers, charge pumps, and other circuitry of the memory device 100.

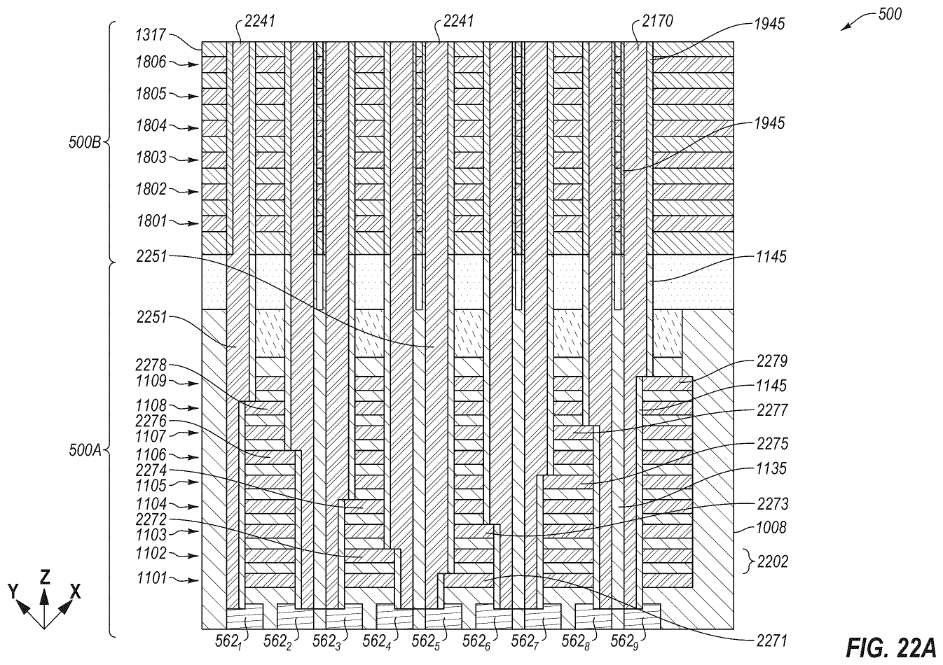

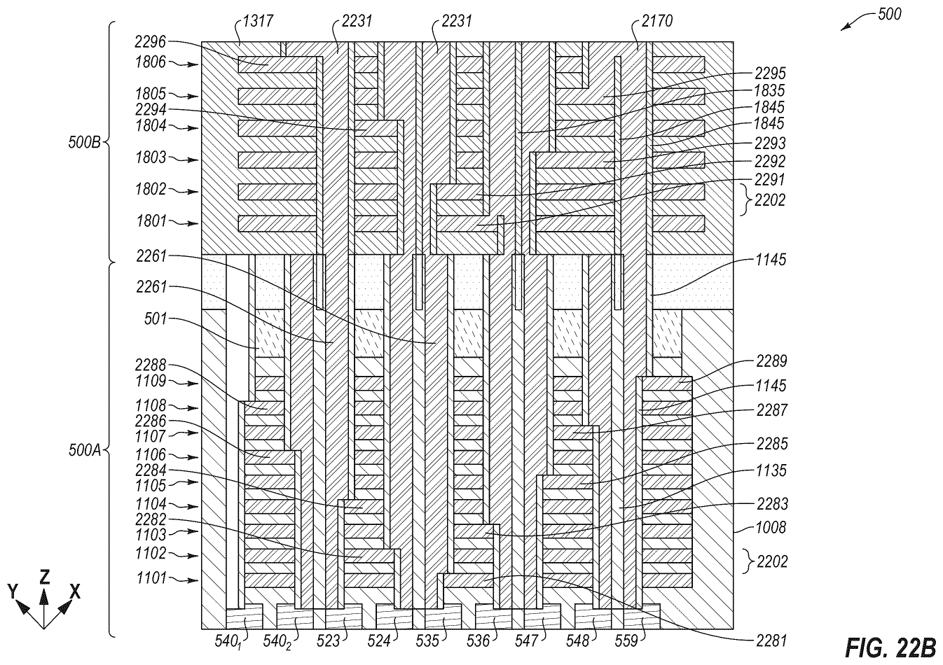

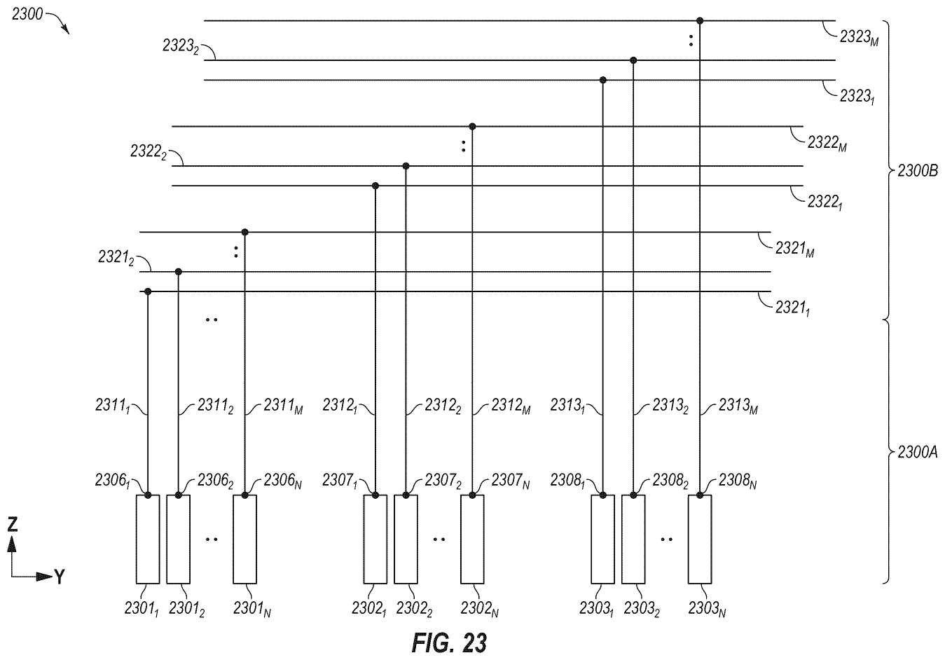

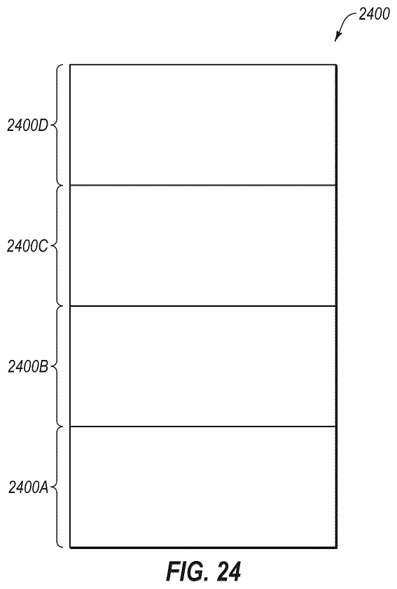

The stack structure of the memory device 100 and of other microelectronic devices (e.g., microelectronic device structure 500 described below with reference to FIG. 5-FIG. 22B, electronic signal processor device 2300 described below with respect to FIG. 23, and microelectronic device structure 2400 described below with respect to FIG. 24) may allow the microelectronic devices according to embodiments of the disclosure to have improvements and benefits over some conventional microelectronic devices. For example, the described stacks of interconnect structures 181₁ through 181_{M}, 182₁ through 182_{M}, 183₁ through 183_{M}, 184₁ through 184_{M}, etc., (FIG. 1-FIG. 4), the stacks of interconnect structures 2291 through 2296 depicted in FIG. 22A and FIG. 22B, the stacked interconnect structures 23211 through 2321_{M}, 2322₁ through 2322_{M}, and 2323₁ through 2323_{M} (depicted in FIG. 23), and the stacked decks 2400A through 2400D (depicted in FIG. 24) may exhibit increased density of interconnect structures for a given device surface area of the microelectronic device relative to some conventional microelectronic devices. This increase in interconnect structure density may allow more microelectronic device components (e.g., more memory cell strings, logic circuits, and/or other types of electronic circuit components) for a given device area to be coupled with the stacked interconnect structures, increasing the microelectronic device component density of the microelectronic device for a given area.

FIG. 6-FIG. 22B show different views of elements during process acts of forming a microelectronic device structure 500 according to some embodiments of the disclosure. Some or all of the process acts used to form the microelectronic device structure 500 may be used to form the memory device 100 described above with reference to FIG. 1-FIG. 4.

FIG. 5 shows a top view of the microelectronic device structure 500 including conductive contacts 540₁ through 540₉ that have been formed. Conductive contacts 540₁ through 540₉ may correspond to conductive contacts 340₁ through 340₉ (depicted in FIG. 3), respectively, of the memory device 100. Conductive contacts 540₁ through 540₉ may be parts of pillars (under conductive contacts 540₁ through 540₉) of memory cell strings (obscured from the top view of FIG. 5) of the microelectronic device structure 500. The memory cell strings and corresponding pillars (which include conductive contacts 540₁ through 540₉) of the microelectronic device structure 500 have been formed in process acts (not described herein) that precede the process acts of forming the microelectronic device structure 500 described with reference to FIG. 5. FIG. 5 also shows other conductive contacts (of other pillars and corresponding memory cell strings) of the microelectronic device structure 500. For the purposes of simplicity and clarity, only some of the other conductive contacts of the microelectronic device structure 500 are labeled, such as conductive contacts 523, 524, 528, 531, 533, 535 through 539, 540₁ through 540₉, 547, 548, 558, 559, 562₁ through 562₉, and 622 through 625.

FIG. 5 also depicts hard masks 501 through 512, formed adjacent to other materials (described in detail below) and to the conductive contacts of the microelectronic device structure 500. Individual hard masks 501 through 512 may be formed to have a length extending in the Y-direction and a width in the X-direction. The material for hard masks 501 through 512 may include tungsten or other materials that may be selectively etchable during process acts (e.g., trimming and/or etching process acts) performed on other materials (e.g., silicon dioxide, silicon nitride, and the material for photo resist structures) during formation of the stacks of data lines of the microelectronic device structure 500.

FIG. 5 further depicts hard masks 570 through 574, formed adjacent to other materials (described in detail below) and to a portion of the hard masks 501 through 512. Individual hard masks 570 through 574 may be formed to have a length extending in the X-direction and a width in the Y-direction. The material for hard masks 570 through 574 may include tungsten or other materials that may be selectively etchable during process acts (e.g., trimming and/or etching process acts) performed on other materials (e.g., silicon dioxide, silicon nitride, and the material for photo resist structures) during formation of the stacks of interconnect structures of the microelectronic device structure 500.

The hard masks 570 through 574 are positioned such that a portion of conductive contacts 523, 524, 528, 531, 533, 535 through 539, 540₁ through 540₉, 547, 548, 558, 559, 562₁ through 562₉, or 622 through 625 are adjacent to respective hard masks 570 through 574 (with respect to the top view) are sides (e.g., in the Y-direction) of the hard masks 570 through 574.

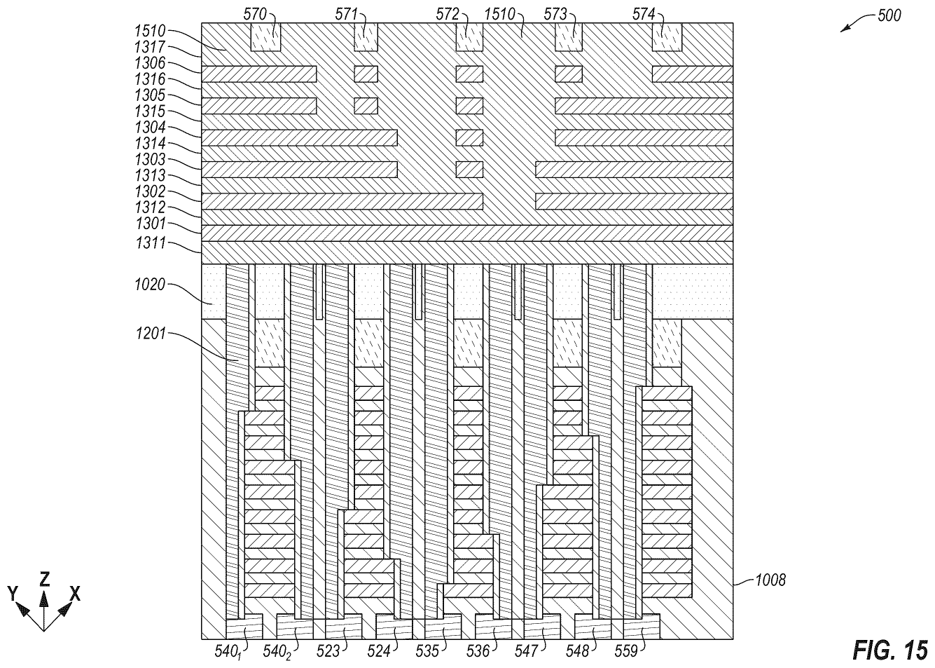

Some process acts of forming the microelectronic device structure 500 associated with FIG. 5 also form other materials (e.g., those shown in FIG. 6) adjacent to (e.g., under) hard masks 501 through 512 and adjacent to (e.g., over) the conductive contacts 523, 524, 528, 531, 533, 535 through 539, 547, 548, 558, 559, 562₁ through 562₉, and 622 through 625 of the microelectronic device structure 500. Additional process acts of forming the microelectronic device structure 500 associated with FIG. 5 also form other materials (e.g., those shown in FIG. 15) adjacent to hard masks 570 through 574 and to hard masks 501 through 512 of the microelectronic device structure 500. Dashed lines A, B, C, and D in FIG. 5 show locations of the microelectronic device structure 500 where different views (e.g., cross sections) of the microelectronic device structure 500 are shown in subsequent figures.

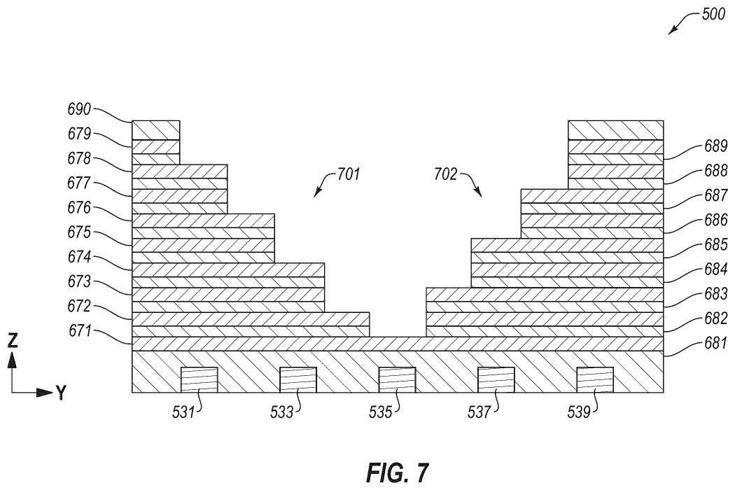

FIG. 5 also shows a location 517 (e.g., an area indicated by the dashed rectangle) that may span across part of the microelectronic device structure 500. As described below (e.g., with reference to FIG. 7), the process acts of forming the stacks of data lines of the microelectronic device structure 500 may include forming a resist structure at location 517 to cover the materials in a portion (e.g., the portion at location 517) of the microelectronic device structure 500. A process described below with reference to FIG. 7 may selectively remove a portion of the materials that is not covered by the resist structure. Such a process is part of forming staircase structures in the materials that are used to form the stacks of data lines of the microelectronic device structure 500.

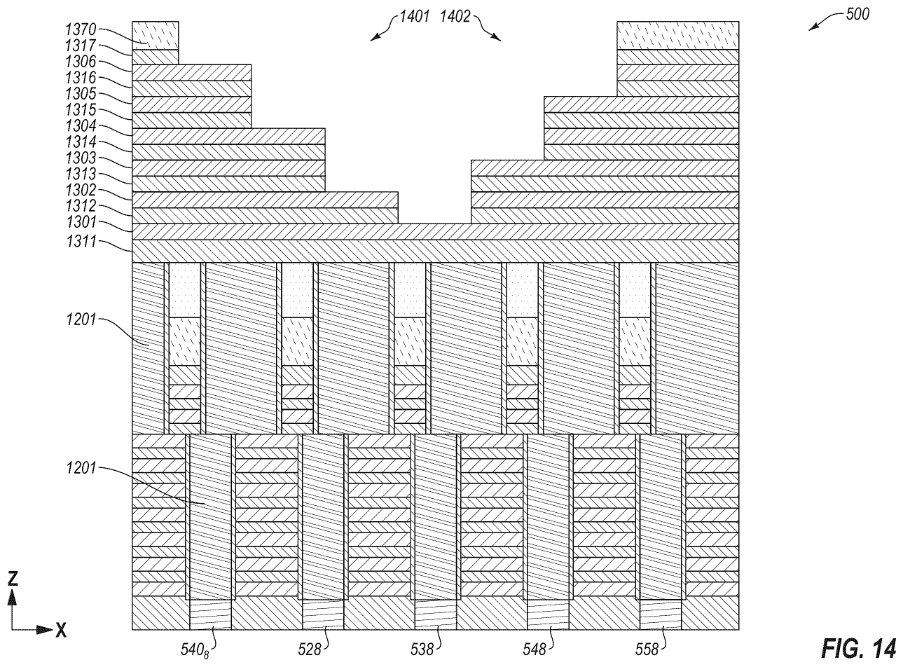

FIG. 5 also shows a location 520 (e.g., an area indicated by the dashed rectangle) that may span across part of the microelectronic device structure 500. As described below (e.g., with reference to FIG. 14), the process acts of forming the stacks of interconnect structures of the microelectronic device structure 500 may include forming a resist structure at location 520 to cover the materials in a portion (e.g., the portion at location 520) of the microelectronic device structure 500. A process described below with reference to FIG. 14 may selectively remove a portion of the materials that is not covered by the resist structure. Such a process is part of forming staircase structures in the materials that are used to form the stacks of interconnect structures of the microelectronic device structure 500.

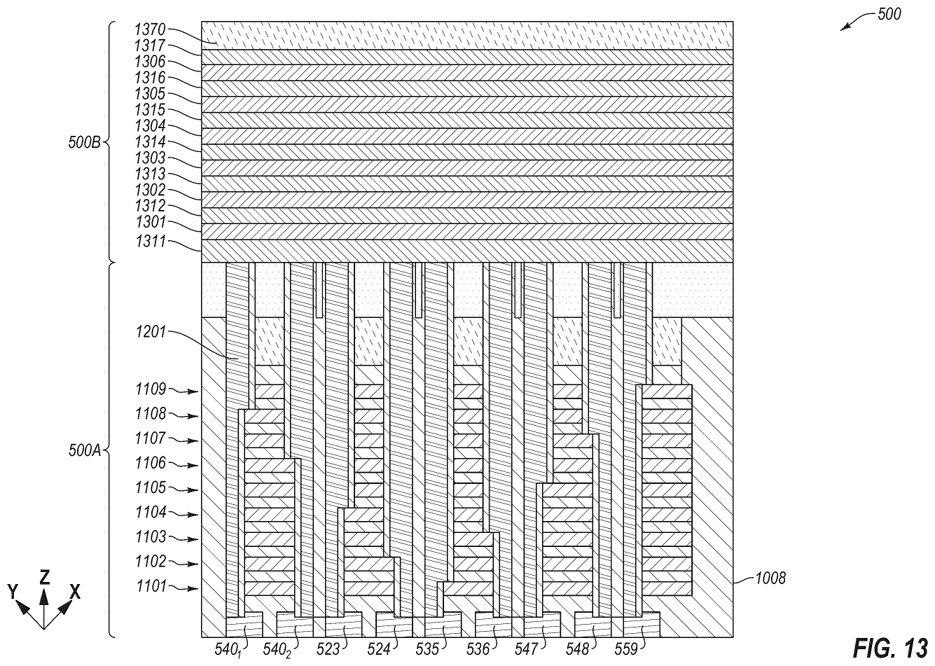

FIG. 6-FIG. 12 depict a process of forming a first (e.g., lower in the Z-direction) deck 500A comprising a stack structure of the microelectronic device structure 500. FIG. 13-FIG. 22B depict a process of forming a second (e.g., relatively higher in the Z-direction than deck 500A) deck 500B comprising a stack structure of the microelectronic device structure 500.

FIG. 6 shows a portion (e.g., a cross section at dashed line A of FIG. 5) of the microelectronic device structure 500 after multiple tiers of materials are formed in respective elevations of the microelectronic device structure 500 adjacent to the conductive contacts 540₂, 622, 623, 624, and 625 of the microelectronic device structure 500.

The tiers of materials (formed in the process acts associated with FIG. 6) include materials 671 through 679 and materials 681 through 690. Materials 671 through 679 may include a sacrificial material (e.g., dielectric nitride, such as SiN_{y}). Materials 681 through 690 may include an insulative material (e.g., silicon dioxide). Materials 671 through 679 and materials 681 through 690 may be formed in a vertically (e.g., in the Z-direction) interleaved (e.g., alternating) fashion, one material after another, adjacent to conductive contacts 540₂, 622, 623, 624, and 625. For example, the process acts may include forming (e.g., depositing) material 681 adjacent to conductive contacts 540₂, 622, 623, 624, and 625, forming material 671 adjacent to material 681, forming material 682 adjacent to material 671, and so on until material 690 is formed.

The insulative materials 681 through 690 of the microelectronic device structure 500 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the materials 681 through 690 of the microelectronic device structure 500 are formed of and include a dielectric oxide material, such as SiOx (e.g., SiO₂). The materials 681 through 690 of the microelectronic device structure 500 may be substantially homogeneous, or the insulative material may be heterogeneous.

Materials 671 through 679 and materials 681 through 690 may also be formed adjacent to other conductive contacts (e.g., the conductive contacts shown in FIG. 5) of the microelectronic device structure 500. However, only a portion along the dashed line A in FIG. 5 of the microelectronic device structure 500 is shown in FIG. 6 for simplicity and clarity.

As shown in FIG. 6, hard masks 501 through 505 may be formed adjacent to materials 671 through 679 and materials 681 through 690. Although not shown in FIG. 6, other hard masks (e.g., hard masks 506 through 512 in FIG. 5) may also be formed adjacent to materials 671 through 679 and materials 681 through 690.

FIG. 7 depicts that in the process acts described with reference to FIG. 6-FIG. 22B, different portions of materials 672 through 679 and materials 682 through 690 are removed (e.g., removed by using an etch process) in one or more process acts (e.g., a distinct etch process). Materials 671 through 679 and materials 681 through 690 under hard masks 501 through 512 (from the view in FIG. 5) may not be removed (e.g., may remain substantially the same), while other portions not under hard masks 501 through 512 of materials 672 through 679 and materials 682 through 690 may be removed.

FIG. 7 shows a portion (e.g., a cross section at dashed line C of FIG. 5) of the microelectronic device structure 500 including a staircase structure that remains following one or more process acts in which portions of materials 672 through 679 and materials 682 through 690 were removed (e.g., removed by using etch process acts). Some of the material 671 may not be removed in the process acts associated with FIG. 7. Thus, a remaining portion of material 671 in FIG. 7 is the same as material 671 in FIG. 6. In FIG. 7, the process acts of removing the portions of materials 672 through 679 and materials 682 through 690 may include using one or more resist structures at location 517 having openings at selected locations. Resist structures may be formed by removing (e.g., trimming) a portion of resist structures at selected locations.

As shown in FIG. 7, the process acts associated with FIG. 7 may form staircase structures 701 and 702 that are opposite from each other, with the stairs of the staircase structure 701 facing, in the Y-direction, the stairs of the staircase structure 702. The stairs of the staircase structure 701 are at uneven elevations with the stairs of the staircase structure 702, such that the top exposed portions of the stairs of the staircase structure 701 of the remaining portions of materials 672, 674, 676, and 678 are at uneven elevations with the top exposed portions of the stairs of the staircase structure 702 of the remaining portions of materials 673, 675, and 677. In other words, a top surface of a stair of the staircase structure 701 and a top surface of a horizontally adjacent stair of the staircase structure 702 are not coplanar. Process acts of forming the uneven staircase structures 701 and 702 associated with FIG. 7 may include using one or more resist structures at location 517 (shown in FIG. 5).

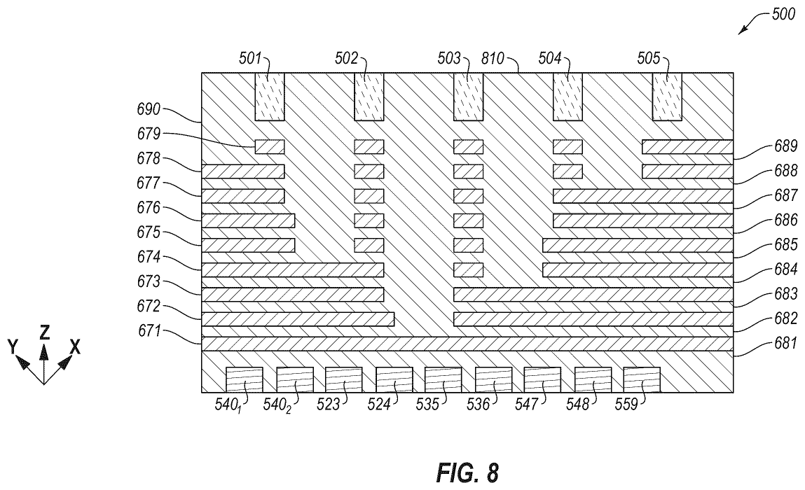

FIG. 8 shows a portion (e.g., a cross section at dashed line D of FIG. 5) of the microelectronic device structure 500 after a material (e.g., dielectric material 810) is formed. The dielectric material 810 may include silicon dioxide. Forming the dielectric material 810 may include depositing an initial silicon dioxide material adjacent to the hard masks 501 through 505 and other materials of the microelectronic device structure 500 shown in FIG. 8. In the view of FIG. 7, initial material may also be deposited (e.g., by filling) the space at the staircase structures 701, 702 of materials 671 through 679 and materials 681 through 690. After depositing (filling) the initial material, a material removal process (e.g., chemical mechanical planarization (CMP) process) may be used to remove a portion (e.g., a top portion) of the initial material and stop at hard masks 501 through 505 (e.g., stopping at the top of hard masks 501 through 505). Thus, hard masks 501 through 505 may be used as etch stops (e.g., a stop material) in the material removal process. The remaining portion of the initial material (after its top portion is removed) is the dielectric material 810.

FIG. 8 shows a portion of the microelectronic device structure 500 including a different view than shown in FIG. 7. As shown in FIG. 5, dashed line D is at an angle (e.g., extending diagonally) relative to the X- and Y-directions, such that the view of the microelectronic device structure 500 in FIG. 8 includes conductive contacts 540₁, 540₂, 523, 524, 535, 536, 547, 548, and 559.

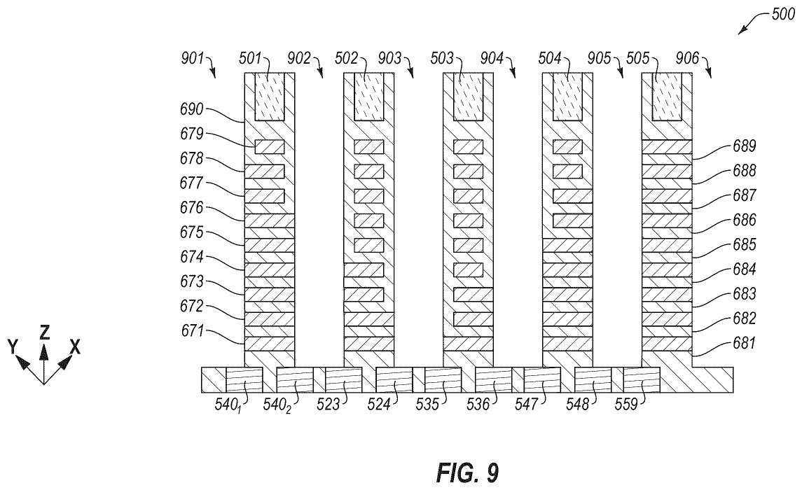

FIG. 9 shows a portion of the microelectronic device structure 500 after openings (e.g., trenches) 901, 902, 903, 904, 905, and 906 are formed. Forming openings 901, 902, 903, 904, 905, and 906 may include removing (e.g., removed by using an etch process) a portion of the dielectric material 810, materials 671 through 679, and materials 681 through 690 at the locations of openings 901, 902, 903, 904, 905, and 906 down to (e.g., down to the top of) conductive contacts 540₁, 540₂, 523, 524, 535, 536, 547, 548, and 559. Thus, the process acts associated with FIG. 9 may include exposing a portion of conductive contacts 540₁, 540₂, 523, 524, 535, 536, 547, 548, and 559 at respective openings 901, 902, 903, 904, 905, and 906.

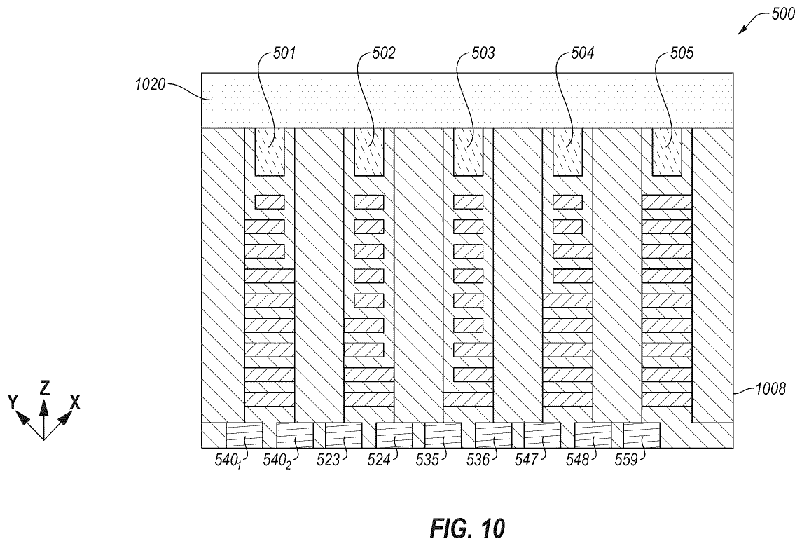

FIG. 10 shows a portion of the microelectronic device structure 500 after a material (e.g., dielectric material 1008) is formed. The dielectric material 1008 may include silicon dioxide. Forming the dielectric material 1008 may include depositing (e.g., filling) an initial material (e.g., silicon dioxide) in the openings 901, 902, 903, 904, 905, and 906 (FIG. 9). The initial material may also be formed adjacent to hard masks 501 through 505, followed by a material removal process (e.g., CMP process) to remove a portion (e.g., a top portion) of the initial material and stop at hard masks 501 through 505 (e.g., stopping at the top of hard masks 501 through 505). Thus, hard masks 501 through 505 may be used as etch stops (e.g., a stop material) in the material removal process. The remaining portion of the initial material (after its top portion is removed) is the dielectric material 1008 shown in FIG. 10.

As also shown in FIG. 10, following formation of material 1008, an etch-stop material 1020 (e.g., carbon nitride) is formed on top (e.g., in the Z-direction) of the dielectric material 1008. Embodiments of the etch-stop material 1020 may include carbon nitride or other materials that may be impervious and/or relatively resistant to process acts (e.g., etching process acts) performed on other materials (e.g., silicon dioxide, silicon nitride, and the material for photo resist structures) during formation of the stacks of data lines of the microelectronic device structure 500.

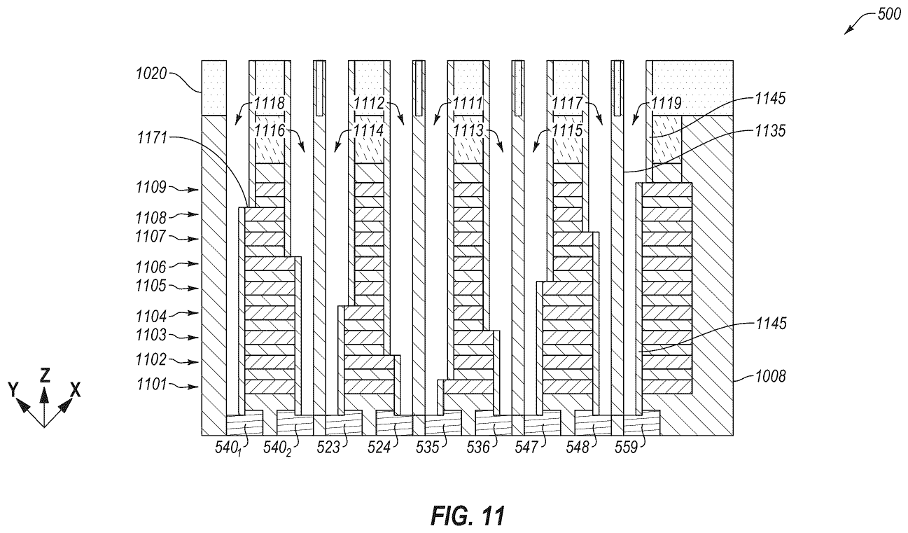

FIG. 11 shows a portion of the microelectronic device structure 500 after openings (e.g., contact openings 1111 through 1119) are formed. Forming the contact openings 1111 through 1119 may include removing (e.g., removed by using an etch process) a portion of the dielectric materials 810 and 1008 and etch-stop material 1020 (e.g., carbon nitride) at the locations of the contact openings 1111 through 1119 down to (e.g., down to the top of) conductive contacts 540₁, 540₂, 523, 524, 535, 536, 547, 548, and 559. Thus, the process acts associated with FIG. 11 may include exposing a portion of conductive contacts 540₁, 540₂, 523, 524, 535, 536, 547, 548, and 559 at respective openings 1111, 1112, 1113, 1114, 1115, 1116, 1117, 1118, and 1119.

The process acts associated with FIG. 11 may include a selective etch process such that materials 671 through 679 located at elevations 1101 through 1109 at the locations of openings 1111 through 1119 are not removed. Thus, the process acts associated with FIG. 11 may include exposing portions (e.g., landing pads 1171) of materials 671 through 679, respectively, at the openings 1111 through 1119, respectively.

The process acts associated with FIG. 11 may include forming isolation structures 1135, such that one of isolation structures 1135 may be positioned between two adjacent conductive contacts among conductive contacts 540₁, 540₂, 523, 524, 535, 536, 547, 548, and 559.

The process acts associated with FIG. 11 may further include forming spacers (e.g., vertical dielectric spacers 1145) on side walls of the etch-stop material 1020, hard masks 501 through 505, materials 671 through 679, materials 681 through 690, and dielectric material 810. Forming spacers 1145 may include depositing a dielectric material (e.g., silicon dioxide) in openings 1111 through 1119 and then removing (e.g., removed by using an etch process) a portion of the dielectric material. The remaining portion of the dielectric material may form spacers 1145, as shown in FIG. 11. Some of the remaining portion of the dielectric material may also be formed on (e.g., formed on sidewalls) isolation structures 1135. For simplicity, FIG. 11 omits reference numerals for the dielectric material formed on isolation structures 1135. As described in subsequent process acts, spacers 1145 may form dielectric structures that electrically separate a respective conductive structure from a respective stack of data lines and/or from a respective stack of interconnect structures. For example, spacers 1145 may correspond to spacers 345 of FIG. 4 that electrically separate a respective conductive structure among conductive structures 314₁, 314₃, 314₅, 314₇, and 314₉ from a respective stack of data lines among data lines 170₁ through 170₉ and/or that electrically separate a respective conductive structure among conductive structures 202₃, 203₃, and 204₃ from a respective stack of interconnect structures among interconnect structures 183₁ through 183₄ (shown in FIG. 4).

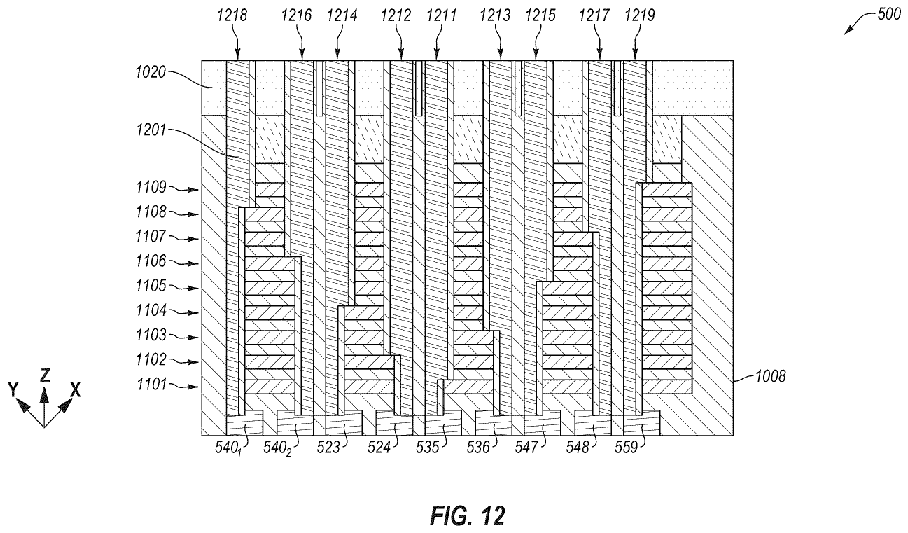

FIG. 12 shows a portion (e.g., a cross section at dashed line D of FIG. 5) of the microelectronic device structure 500 after a material (e.g., sacrificial material 1201) is formed within openings 1111 through 1119. The sacrificial material 1201 may include aluminum oxide. In various embodiments of the disclosure, the sacrificial material 1201 may exhibit a selected selectivity to process acts (e.g., etching process acts) relative to other materials 810, 671 through 679, 681 through 690, 1008, and 1020 of the microelectronic device structure 500. Forming the sacrificial material 1201 may include depositing an initial material (e.g., aluminum oxide) into the openings 1111 through 1119 and on top (e.g., in the Z-direction) of the etch-stop material 1020 and other materials of the microelectronic device structure 500 shown in FIG. 12. After depositing (filling) the initial material, which substantially completely fills the openings 1111 through 1119, a material removal process act (e.g., CMP process) may be conducted to remove a portion (e.g., a top portion) of the initial material and stop at etch-stop material 1020. Thus, etch-stop material 1020 may be used as a stop material in the material removal process. The remaining portion of the initial material (after its top portion is removed) is sacrificial material 1201 shown in FIG. 12. Upon conducting the process acts described with reference to FIG. 12, the microelectronic device structure 500 includes structures (e.g., contact structures 1211 through 1219), wherein the sacrificial material 1201 was formed within openings (e.g., contact openings) 1111 through 1119.

The following discussion, with respect to FIG. 13-FIG. 22B, sets forth an example process of forming a second (e.g., relatively higher in the Z-direction than deck 500A) deck 500B comprising a stack structure of the microelectronic device structure 500.

FIG. 13 shows a portion (e.g., a cross section at dashed line D of FIG. 5) of the microelectronic device structure 500 after tiers of materials are formed in respective elevations of the microelectronic device structure 500 adjacent to the etch-stop material 1020 and to the contact structures 1211 through 1219 (shown in FIG. 12) of first deck 500A of the microelectronic device structure 500. The tiers of materials include materials 1301 through 1306 and materials 1311 through 1317. Materials 1301 through 1306 may include a sacrificial material (e.g., dielectric nitride, such as SiN_{y}). Materials 1311 through 1317 may include an insulative material (e.g., silicon dioxide). Materials 1301 through 1306 and materials 1311 through 1317 may be formed in a vertically (e.g., in the Z-direction) interleaved (e.g., alternating) fashion, one material after another, adjacent to the etch-stop material 1020 and to the contact structures 1211 through 1219. For example, the process acts associated with FIG. 13 may include forming (e.g., depositing) material 1311 adjacent to the etch-stop material 1020 and to the contact structures 1211 through 1219, forming (e.g., depositing) material 1301 adjacent to the material 1311, forming (e.g., depositing) material 1312 adjacent to material 1301, and so on until material 1317 is formed. Hard mask (e.g., hard mask material 1370) may be formed adjacent to material 1317.

The materials 131₁ through 1317 of the microelectronic device structure 500 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the materials 131₁ through 1317 of the microelectronic device structure 500 are formed of and include a dielectric oxide material, such as SiOx (e.g., SiO₂). The materials 131₁ through 1317 of the microelectronic device structure 500 may be substantially homogeneous, or the insulative material may be heterogeneous.

In the embodiment of the microelectronic device structure 500 depicted in FIG. 13, materials 131₁ through 1317 comprise seven different structures (e.g., silicon dioxide), while materials 1301 through 1306 comprise six different structures (e.g., silicon nitride). However, other embodiments of the microelectronic device structure 500 comprise varying quantities of alternating structures (e.g., silicon dioxide and/or silicon nitride).

Materials 1301 through 1306 and materials 1311 through 1317 are also formed adjacent to other contact structures of first deck 500A of the microelectronic device structure 500. However, for the purpose of simplicity, only a portion (e.g., portion along dashed line D in FIG. 5) of the microelectronic device structure 500 is shown in FIG. 13.

In the process acts associated with FIG. 14, hard masks 570 through 574 (depicted in FIG. 5) may be formed from hard mask material 1370 adjacent to the materials 1301 through 1306 and materials 1311 through 1317. Although not shown in FIG. 14, other hard masks may also be formed adjacent to the materials 1301 through 1306 and materials 1311 through 1317.

FIG. 14 shows a portion (e.g., a cross section at dashed line B of FIG. 5) of the microelectronic device structure 500 after different portions of materials 1302 through 1306 and materials 1312 through 1317 are removed (e.g., removed by using an etch process) in one or more process acts (e.g., a distinct etch process). Materials 1301 through 1306 and materials 1311 through 1317 under hard masks 570 through 574 (from the view in FIG. 5) may not be removed (e.g., may remain substantially the same), while other portions (e.g., portions not under hard masks 570 through 574) of materials 1302 through 1306 and materials 1312 through 1317 may be removed.

FIG. 14 shows that deck 500B of the microelectronic device structure 500 includes a staircase structure that remains following one or more process acts in which portions of materials 1302 through 1306 and materials 1312 through 1317 were removed (e.g., removed by using etch process acts). Material (e.g., silicon nitride) 1301 may not be removed in the process acts associated with FIG. 14. Thus, a remaining portion of material 1301 in FIG. 14 is the same as material 1301 in FIG. 13. In FIG. 14, the process acts of removing the portions of materials 1302 through 1306 and materials 1312 through 1317 may include using one or more resist structures having openings at selected locations. Resist structures may be formed by removing (e.g., trimming) a portion of resist structures at selected locations.

As shown in FIG. 14, the process acts associated with FIG. 14 may form staircase structures 1401 and 1402 that are opposite from each other (e.g., the stairs of staircase structure 1401 are facing the stairs of staircase structure 1402 in the X-direction). The stairs of staircase structure 1401 are at uneven elevations with the stairs of staircase structure 1402, such that the top exposed portions of the staircase structure 1401 of the remaining portions of materials 1302, 1304, and 1306 are at uneven elevations with the top exposed portions of staircase structure 1402 of the remaining portions of materials 1303 and 1305. In other words, a top surface of a stair of the staircase structure 1401 and a top surface of a horizontally adjacent stair of the staircase structure 1402 are not coplanar. Process acts of forming the uneven staircase structures 1401 and 1402 associated with FIG. 14 may include using one or more resist structures at location 520 (shown in FIG. 5).

FIG. 15 shows a portion (e.g., a cross section at dashed line D of FIG. 5) of the microelectronic device structure 500 after a material 1510 (e.g., dielectric material) is formed. Material 1510 may include silicon dioxide. Forming material 1510 may include depositing an initial material (e.g., silicon dioxide) adjacent to the hard masks 570 through 574 and other materials of the microelectronic device structure 500 shown in FIG. 15. In the view of FIG. 14, initial material may also be deposited in (e.g., filling) the space at the staircase structures 1401, 1402 of materials 1301 through 1306 and materials 1311 through 1317. After depositing (filling) the initial material, a material removal process (e.g., chemical mechanical planarization (CMP) process) may be used to remove a top portion of the initial material and stop at the hard masks 570 through 574 (e.g., stop at the top of hard masks 570 through 574). Thus, hard masks 570 through 574 may be used as etch stops (e.g., a stop material) in the material removal process. The remaining portion of the initial material (after its top portion is removed) is material 1510.

FIG. 15 shows a portion of the microelectronic device structure 500 including a different view than shown in FIG. 14. As shown in FIG. 5, dashed line D is at an angle (e.g., extending diagonally) relative to the X- and Y-directions, such that the view of the microelectronic device structure 500 in FIG. 15 includes conductive contacts 540₁, 540₂, 523, 524, 535, 536, 547, 548, and 559.

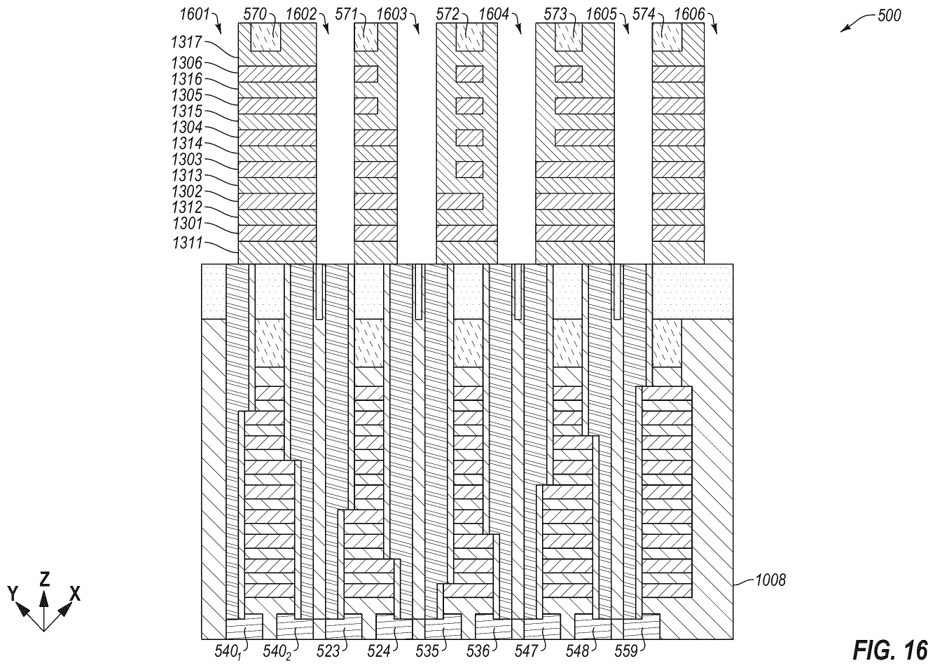

FIG. 16 shows a cross section at dashed line D of FIG. 5 of the microelectronic device structure 500 after openings (e.g., trenches) 1601, 1602, 1603, 1604, 1605, and 1606 are formed. Forming openings 1601, 1602, 1603, 1604, 1605, and 1606 may include removing (e.g., removed by using an etch process) a portion of material 1510, materials 1301 through 1306, and materials 1311 through 1317 at the locations of openings 1601, 1602, 1603, 1604, 1605, and 1606 down to (e.g., down to the top of) individual contact structures 1211 through 1219 (shown in FIG. 12) of deck 500A. Thus, the process acts associated with FIG. 16 may include exposing a portion of one or more of the contact structures 1211 through 1219 at openings 1601, 1602, 1603, 1604, 1605, and 1606.

As shown in FIG. 16, contact structures 1216 and 1217 (shown in FIG. 12) were not exposed to any of the openings 1601, 1602, 1603, 1604, 1605, or 1606. However, in other embodiments of the disclosure, various portions of contact structures 1211 through 1219, including all contact structures, may be exposed by such openings 1601, 1602, 1603, 1604, 1605, or 1606. In embodiments of the disclosure, the quantity of materials 1301 through 1306 may indicate the quantity of openings 1601, 1602, 1603, 1604, 1605, or 1606 that may individually expose an equivalent number of contact structures 1211 through 1219. Thus, in the embodiment of the microelectronic device structure 500 depicted in FIG. 16, deck 500B comprises six tiers of materials 1301 through 1306, indicating that six contact structures 1211 through 1219 may be exposed through openings 1601, 1602, 1603, 1604, 1605, or 1606. However, in other embodiments, the microelectronic device structure 500 may be formed to include any desired quantity of tiers. By way of non-limiting example, the microelectronic device structure 500 may be formed to include greater than or equal to sixteen (16) tiers of materials 1301 through 1306, such as greater than or equal to thirty-two (32) tiers 1301 through 1306, greater than or equal to sixty-four (64) tiers of materials 1301 through 1306, greater than or equal to one hundred and twenty-eight (128) tiers of materials 1301 through 1306, or greater than or equal to two hundred and fifty-six (256) tiers 1301 through 1306.

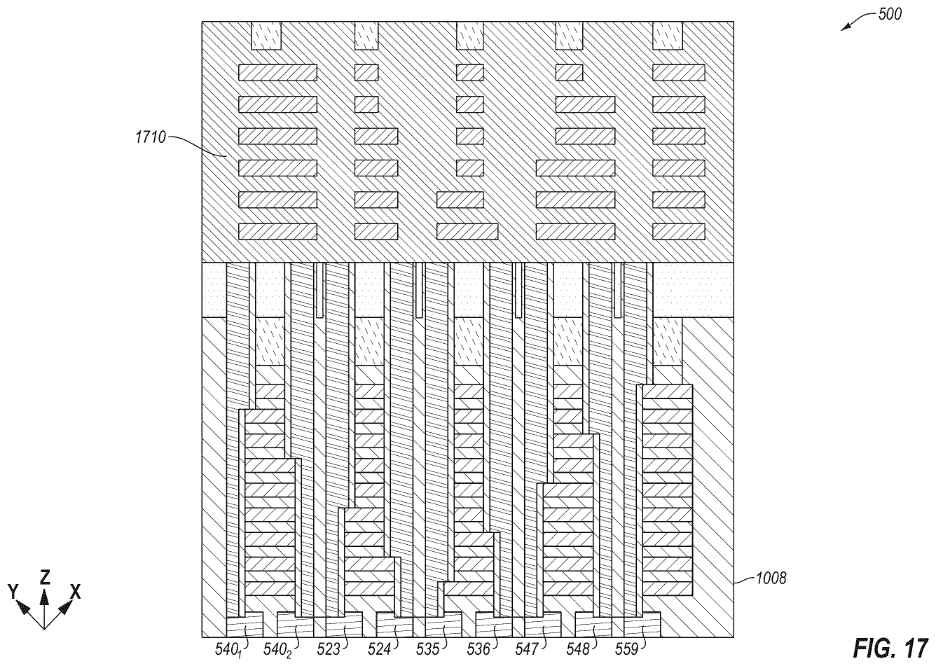

FIG. 17 shows a portion (e.g., a cross section at dashed line D of FIG. 5) of the microelectronic device structure 500 after a material (e.g., dielectric material) 1710 is formed. Material 1710 may include silicon dioxide. Forming material 1710 may include depositing (e.g., filling) an initial material (e.g., silicon dioxide) in openings 1601, 1602, 1603, 1604, 1605, and 1606. The initial material may also be formed adjacent to the hard masks 570 through 574, followed by a material removal process to remove a top portion of the initial material and stop at hard masks 570 through 574 (e.g., stop at the top of hard masks 570 through 574). Thus, hard masks 570 through 574 may be used as etch stops (e.g., a stop material) in the material removal process. The remaining portion of the initial material (after its top portion is removed) is material 1710 shown in FIG. 17.

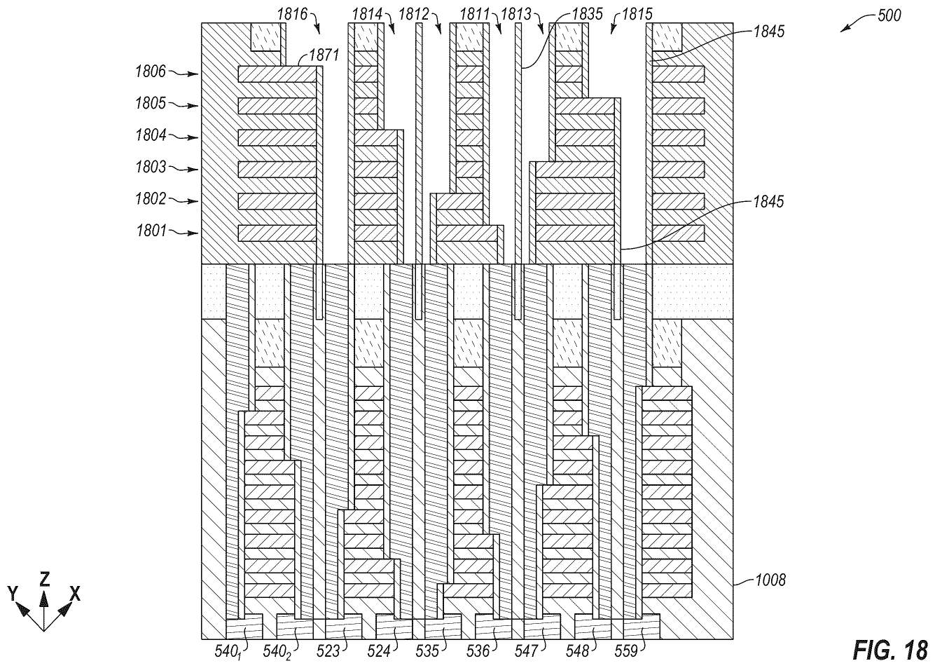

In some embodiments of the disclosure, it may be desirable to form another deck (not shown) above (e.g., in the Z-direction) deck 500B of the microelectronic device structure 500. In such cases, following formation of material 1710, another etch-stop material (e.g., carbon nitride) similar to etch-stop material 1020 (set forth above in the description with reference to FIG. 10) may be formed on top (e.g., in the Z-direction) of material 1710. Thereafter, the process acts described with reference to FIG. 11-FIG. 17, including forming a subsequent deck above (e.g., in the Z-direction) deck 500B as described with reference to FIG. 13, may be serially repeated as many times as desired, with a cycle resulting in an additional deck of the microelectronic device structure 500 formed (e.g., stacked) above (e.g., in the Z-direction) previously-formed deck(s), and continued until a desired quantity of stacked decks on the microelectronic device structure 500 have been formed. Thereafter, process acts set forth below with reference to FIG. 18-FIG. 22B may be followed.

FIG. 18 shows a portion (e.g., a cross section at dashed line D of FIG. 5) of the microelectronic device structure 500 after contact openings 1811 through 1816 are formed. Forming contact openings 1811 through 1816 may include removing a portion of materials 1510 and 1710 at the locations of openings 1811 through 1816 down to (e.g., down to the top of) one or more of the contact structures 1211 through 1219 (shown in FIG. 12) of the lower deck 500A of the microelectronic device structure 500. Thus, the process associated with FIG. 18 may include exposing a portion of one or more of the contact structures 1211 through 1219 of first deck 500A of the microelectronic device structure 500 at respective openings 1811, 1812, 1813, 1814, 1815, and 1816.

The process acts associated with FIG. 18 may include a selective etch process such that materials 1301 through 1306 located at elevations 1801 through 1806 at the locations of openings 1811 through 1816 are not removed. Thus, the process acts associated with FIG. 18 may include exposing landing pads 1871 of the sacrificial materials 1301 through 1306, respectively, at the locations of openings 1811 through 1816, respectively.

The process associated with FIG. 18 may include forming isolation structures 1835, such that one of isolation structures 1835 may be positioned horizontally between two adjacent contact structures among contact structures 1211 through 1219 (FIG. 12).

The process associated with FIG. 18 may further include forming spacers 1845 (e.g., vertical dielectric spacers) on side walls of the hard masks 570 through 574, materials 1301 through 1306, materials 1311 through 1317, and the dielectric material 1510. Forming spacers 1845 may include depositing a dielectric material (e.g., silicon dioxide) in openings 1811 through 1816 and then removing (e.g., removed by using an etch process) a portion of the dielectric material. The remaining portion of the dielectric material may form spacers 1845, as shown in FIG. 18. Some of the remaining portion of the dielectric material may also be formed on (e.g., formed on sidewalls) individual isolation structures 1835. For simplicity, FIG. 18 omits reference numerals for the dielectric material formed on isolation structures 1835. As described in subsequent process acts, spacers 1845 may form dielectric structures that electrically separate a respective conductive structure from a respective stack of data lines and/or from a respective stack of interconnect structures. For example, spacers 1845 may correspond to spacers 345 of FIG. 4 that electrically separate a respective conductive structure among conductive structures 314₁, 314₃, 314₅, 314₇, and 314₉ from a respective stack of data lines among data lines 170₁ through 170₉ and/or that electrically separate a respective conductive structure among conductive structures 202₃, 203₃, and 204₃ from a respective stack of interconnect structures among interconnect structures 183₁ through 183₄ (shown in FIG. 4).

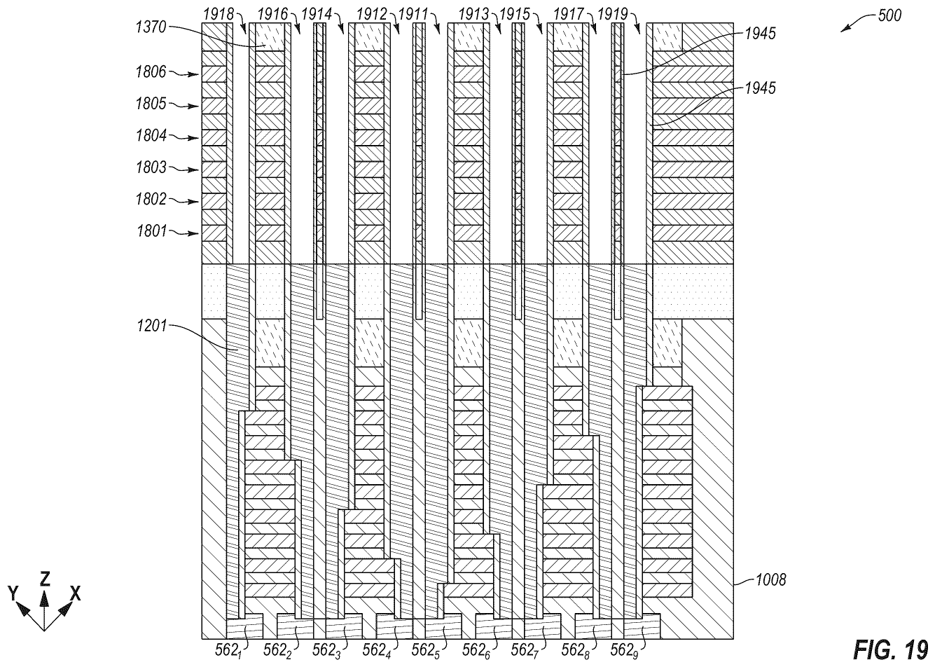

FIG. 19 shows a portion (e.g., a cross section at dashed line E of FIG. 5) of the microelectronic device structure 500 after contact openings 1911 through 1919 are formed. Openings 1911 through 1919 may be formed in the upper deck 500B at a location where the staircase structures 1401 and 1402 were not formed, or where materials 1301 through 1306 and materials 1311 through 1317 were otherwise not previously removed. Forming openings 1911 through 1919 may include removing (e.g., removed by using an etch process) a portion of materials (e.g., silicon oxide) 1510 and/or 1710 (if present at the selected location for openings 1911 through 1919), hard mask material 1370, materials 1301 through 1306, and materials 1311 through 1317 at the locations of openings 1911 through 1919 down to (e.g., down to the top of) one or more of the contact structures 1211 through 1219 (shown in FIG. 12) of the lower deck 500A of the microelectronic device structure 500. Thus, the process associated with FIG. 19 may include exposing a portion of one or more of the contact structures 1211 through 1219 of first deck 500A of the microelectronic device structure 500 at respective openings 1911 through 1919.

The process associated with FIG. 19 may further include forming spacers 1945 (e.g., vertical dielectric spacers) on side walls of the hard masks 570 through 574, materials 1301 through 1306, and materials 1311 through 1317. Forming spacers 1845 may include depositing a dielectric material (e.g., silicon dioxide) in openings 1911 through 1919 and then removing (e.g., removed by using an etch process) a portion of the dielectric material. The remaining portion of the dielectric material may form spacers 1945, as shown in FIG. 19. As described in subsequent process acts, spacers 1945 may form dielectric structures that electrically separate a respective conductive structure from a respective stack of data lines and/or from a respective stack of interconnect structures. For example, spacers 1845 may correspond to spacers 345 of FIG. 4 that electrically separate a respective conductive structure among conductive structures 314₁, 314₃, 314₅, 314₇, and 314₉ from a respective stack of data lines among data lines 170₁ through 170₉ and/or that electrically separate a respective conductive structure among conductive structures 202₃, 203₃, and 204₃ from a respective stack of interconnect structures among interconnect structures 183₁ through 183₄ (shown in FIG. 4).

The process acts described with reference to FIG. 19 may be conducted as part of a sequence differing from the ordering of FIG. 14-FIG. 19. In other words, there is no specific sequence of process acts implied by the ordering of the drawings in the disclosure. For example, the process acts described with reference to FIG. 19 may be conducted after conducting the process acts described with reference to FIG. 5-FIG. 13 but prior to conducting the process acts described with reference to FIG. 14-FIG. 18. In other examples, one or more process acts described with reference to FIG. 19 may be conducted simultaneously with one or more of the process acts described with reference to FIG. 14-FIG. 18. In some examples, the process acts described with reference to FIG. 19 are conducted at substantially the same time as the process acts described with reference to FIG. 18. More particularly, forming the contact openings 1811 through 1816 and forming the contact openings 1911 through 1919 may be conducted as concurrent process acts. Likewise, forming vertical dielectric spacers 1845 on side walls of respective openings 1811 through 1816 and forming vertical dielectric spacers 1945 on side walls of respective openings 1911 through 1919 may be conducted as concurrent process acts.

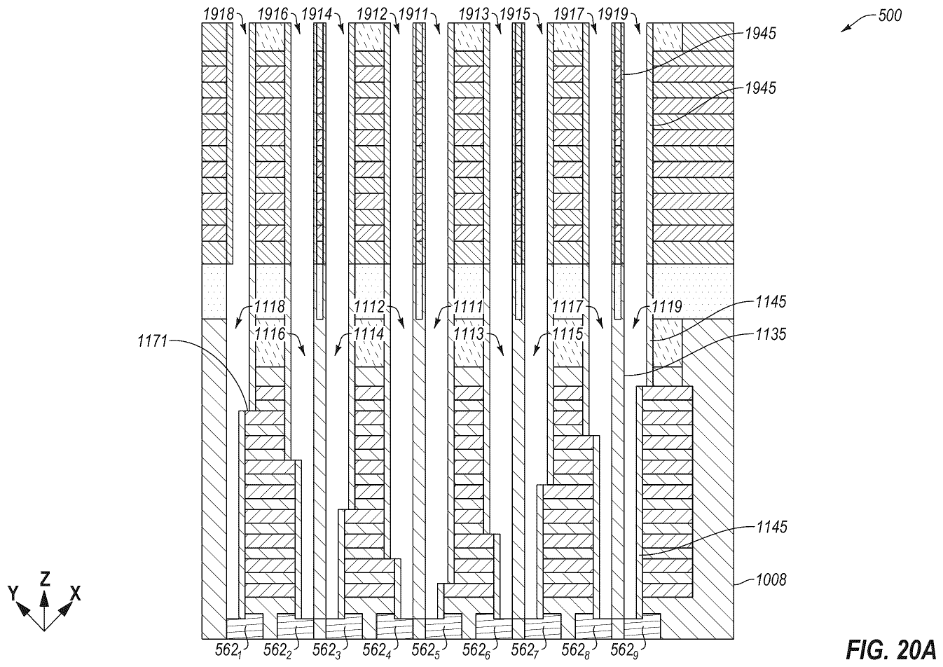

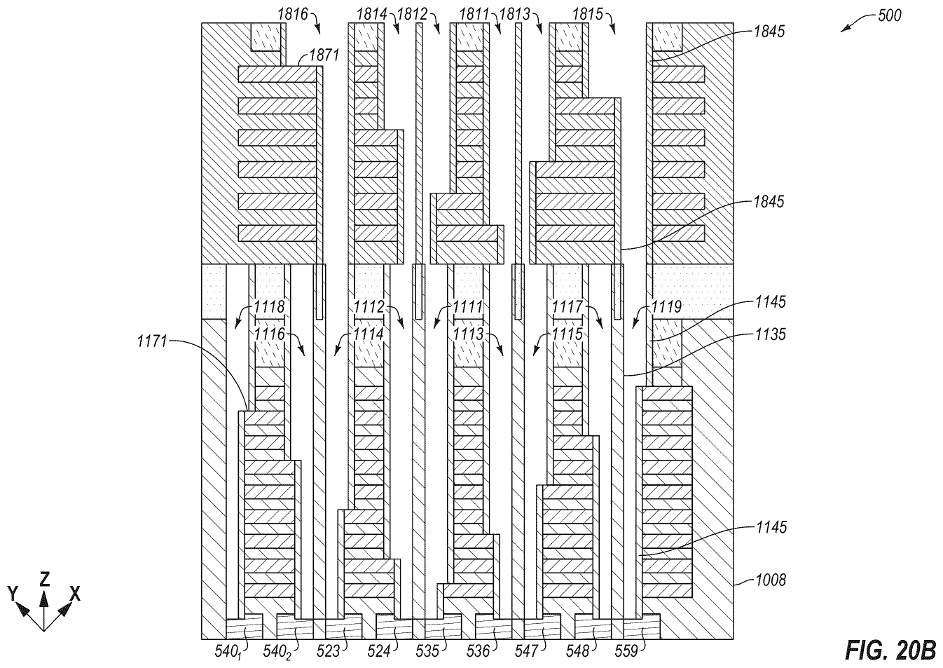

FIG. 20A shows a portion (e.g., a cross section at dashed line E of FIG. 5) and FIG. 20B shows a portion (e.g., a cross section at dashed line D of FIG. 5) of the microelectronic device structure 500 after material 1201 (e.g., sacrificial material) is removed (e.g., exhumed) from contact openings 1111 through 1119 via contact openings 1811 through 1816 and via contact openings 1911 through 1919, respectively. Thus, the process associated with FIG. 20A and FIG. 20B may include forming openings at the locations that were occupied by material 1201. The contact openings 1911 through 1919 in combination with the openings previously occupied by material 1201 extend through the second deck 500B and into the first deck 500A.

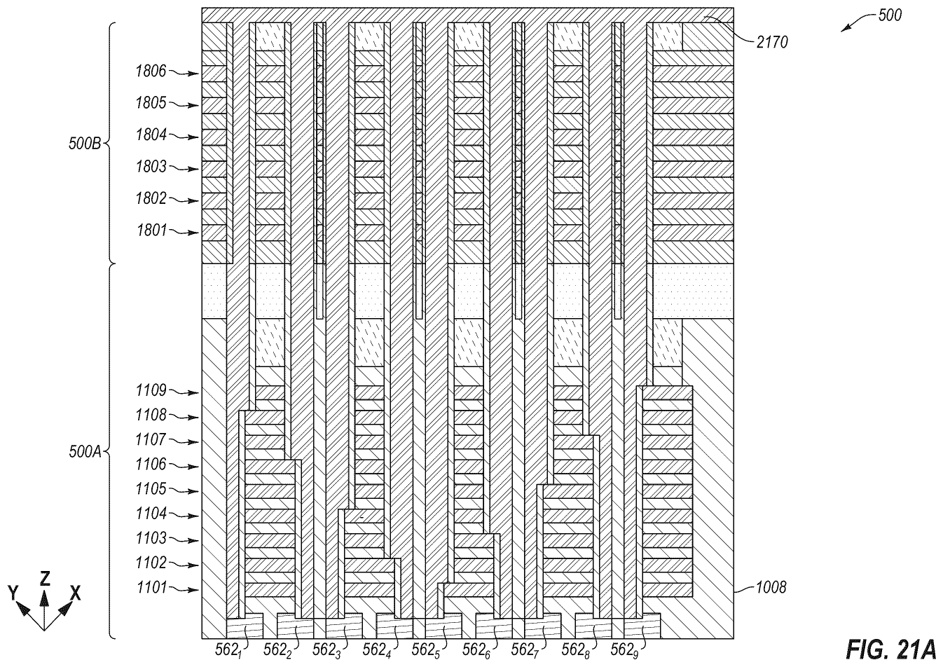

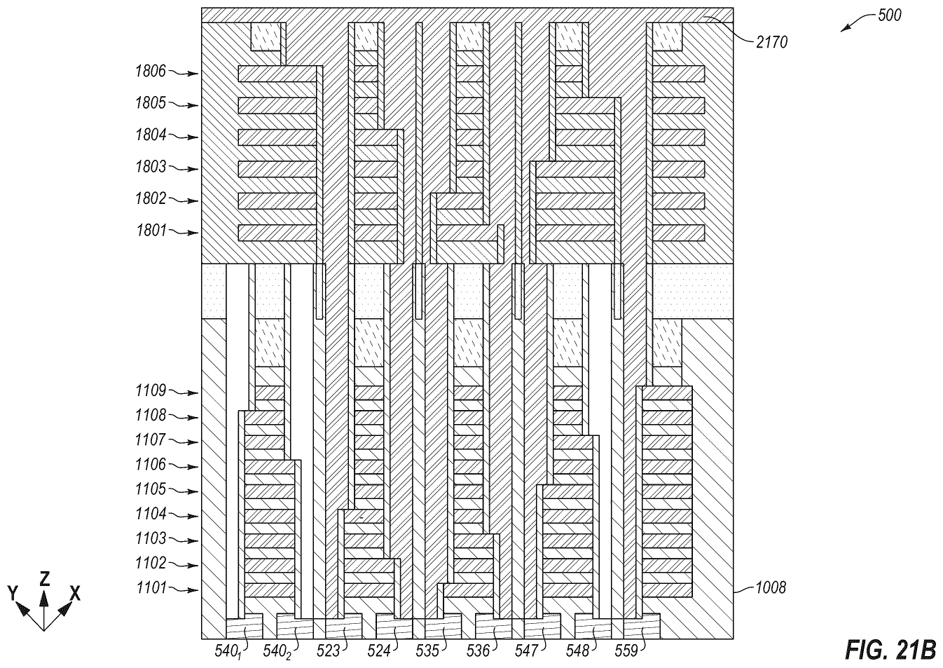

FIG. 21A shows a portion (e.g., a cross section at dashed line E of FIG. 5) and FIG. 21B shows a portion (e.g., a cross section at dashed line D of FIG. 5) of the microelectronic device structure 500 after materials 671 through 679 and materials 1301 through 1306 are removed (e.g., exhumed).

Further, FIG. 21A and FIG. 21B show a portion of the microelectronic device structure 500 after a conductive material 2170 is formed. Conductive material 2170 may be formed in deck 500A at elevations 1101 through 1109 and in contact openings 1111 through 1119; and in deck 500B at elevations 1801 through 1806 and in contact openings 1811 through 1816 and in contact openings 1911 through 1919. Process acts of forming conductive material 2170 may include depositing conductive material 2170 in openings 1811 through 1816, contact openings 1911 through 1919, contact openings 1111 through 1119, and in the openings at the locations that were previously occupied by materials 671 through 679 and materials 1301 through 1306. After conductive material 2170 has been formed as shown in FIG. 21A and FIG. 21B, the interleaved (e.g., alternating) tiers of conductive material 2170 and vertically neighboring insulative material 681 through 690 and 1311 through 1317 may form tiers 2202 of the microelectronic device structure 500, wherein an individual tier 2202 comprises materials 681 through 690 or materials 1311 through 1317 formed below (e.g., in the Z-direction) a conductive material 2170.

The conductive material 2170 of individual tiers 2202 of the microelectronic device structure 500 may be formed of and include one or more of at least one metal, at least one alloy, and at least one conductive metal-containing material (e.g., at last one conductive metal nitride, at least one conductive metal silicide, at least one conductive metal carbide, at least one conductive metal oxide), and least one conductively doped semiconductor material (e.g., conductively doped polysilicon). In some embodiments, the conductive material 2170 is formed of and includes tungsten (W). Optionally, at least one liner material (e.g., at least one conductive liner material) may be formed around the conductive material 2170. The liner material may, for example, be formed of and include one or more of a metal (e.g., Ti, Ta), an alloy, and a metal nitride (e.g., TiN_{y}, TaN_{y}). In some embodiments, the liner material comprises at least one conductive material employed as a seed material for the formation of the conductive material 2170. In some embodiments, the liner material comprises titanium nitride (TiNₓ, such as TiN). As a non-limiting example, TiNₓ (e.g., TiN) may be formed directly adjacent the materials 681 through 690 or materials 1311 through 1317, and W may be formed directly adjacent the TiNₓ. For clarity and ease of understanding the description, the liner material is not illustrated, but it is understood that the liner material may be disposed around the conductive material 2170. The conductive material 2170 of individual tiers 2202 may be formed through a so-called “replacement” process wherein sacrificial material of tiers 671 through 679 and 1301 through 1306 of a preliminary stack structure is selectively removed (e.g., using a wet etchant comprising phosphoric acid (H₃PO₄)), and then the resulting voids are filled with conductive material to form the conductive material 2170.

Optionally, one or more liner materials(s) (e.g., conductive wire material(s)) may also be formed around the conductive material 2170. The liner material(s) may, for example, be at least one conductive material formed of and including one or more of a metal (e.g., titanium, tantalum), an alloy, and a metal nitride (e.g., tungsten nitride, titanium nitride, tantalum nitride). In some embodiments, the liner material(s) comprise at least one conductive material employed as a seed material for the formation of the conductive material 2170. In some embodiments, the liner material(s) comprise titanium nitride. As a non-limiting example, titanium nitride may be formed directly adjacent the materials 681 through 690 or materials 1311 through 1317, and tungsten may be formed directly adjacent the titanium nitride. For clarity and ease of understanding the description, the liner material(s) are not illustrated in the drawings herein, but it will be understood that the liner material(s) may be disposed around the conductive material 2170.

FIG. 22A shows a portion (e.g., a cross section at dashed line E of FIG. 5) and FIG. 22B shows a portion (e.g., a cross section at dashed line D of FIG. 5) of the microelectronic device structure 500 after a portion (e.g., top portion of conductive material 2170) and hard masks 570 through 574 are removed. The process associated with FIG. 22A and FIG. 22B may include a material removal process (e.g., CMP process) that may remove a top portion of conductive material 2170 and the hard masks 570 through 574 and stop at the elevation of the material 1710 right below hard masks 570 through 574.

As shown in FIG. 22A and FIG. 22B, the process acts associated with FIG. 22A and FIG. 22B may form data lines 2271 through 2279, data lines 2281 through 2289, interconnect structures 2291 through 2296, conductive structures 2241, conductive structures 2251, conductive structures 2231, and conductive structures 2261. Data lines 2271 through 2279 and data lines 2281 through 2289 may be located in elevations 1101 through 1109, respectively, of deck 500A of the microelectronic device structure 500. Interconnect structures 2291 through 2296 may be located in elevations 1801 through 1806, respectively, of deck 500B of the microelectronic device structure 500.

FIG. 22A shows a view of the microelectronic device structure 500 along dashed line E of FIG. 5. Thus, data lines 2271 through 2279 may be parts of five respective stacks of data lines of the microelectronic device structure 500 located side by side in the X-direction of FIG. 5 and on the same elevation of the microelectronic device structure 500. For example, data lines 2276 and 2278 may be two data lines of a stack of nine data lines located under (e.g., directly under) the hard mask 506 in FIG. 5. Data lines 2272 and 2274 may be two data lines of a stack of nine data lines located under the hard mask 507 in FIG. 5. Data lines 2271 and 2273 may be two data lines of a stack of nine data lines located under the hard mask 508 in FIG. 5. Data lines 2275 and 2277 may be two data lines of a stack of nine data lines located under the hard mask 509 in FIG. 5. Data line 2279 may be a data line of a stack of nine data lines located under the hard mask 510 in FIG. 5.

As further examples, data lines 2276 and 2278 in FIG. 22A may be two data lines among the set of data lines 170₁ through 170₉ of the memory device 100 of FIG. 1 and data lines 2272 and 2274 in FIG. 22A may be two data lines among the set of data lines 171₁ through 171₉ of the memory device 100 of FIG. 1.

FIG. 22B shows a view of the microelectronic device structure 500 along dashed line D of FIG. 5. Thus, data lines 2281 through 2289 may be parts of five respective stacks of data lines of the microelectronic device structure 500, located side by side in the X-direction of FIG. 5 and on the same elevation of the microelectronic device structure 500. For example, data lines 2286 and 2288 may be two data lines of a stack of nine data lines located under the hard mask 501.

Likewise, interconnect structures 2291 through 2296 may be parts of five respective stacks of interconnect structures of the microelectronic device structure 500, located side by side in the Y-direction of FIG. 5 and on the same elevation of the microelectronic device structure 500. For example, interconnect structure 2296 may be an interconnect structure of a stack of six interconnect structures located under the hard mask 570 in FIG. 5. Interconnect structure 2294 may be an interconnect structure of a stack of six interconnect structures located under the hard mask 571 in FIG. 5. Interconnect structures 2291 and 2292 may be two interconnect structures of a stack of six interconnect structures located under the hard mask 572 in FIG. 5. Interconnect structures 2293 and 2295 may be two interconnect structures of a stack of six interconnect structures located under the hard mask 573 in FIG. 5.

As further examples, data lines 2285 and 2287 in FIG. 22B may be two data lines among the set of data lines 170₁ through 170₉ of the memory device 100 of FIG. 1 and data line 2289 in FIG. 22B may be a data line among the set of data lines 171₁ through 171₉ of the memory device 100 of FIG. 1. Interconnect structures 2293 and 2295 in FIG. 22B may be two interconnect structures among the set of interconnect structures 181₁ through 181_{M} of the memory device 100 of FIG. 1. Interconnect structure 2293 in FIG. 22B may be electrically coupled to data line 2285 via corresponding conductive structures 2231 and 2261. Interconnect structure 2295 in FIG. 22B may be electrically coupled to data line 2289 via corresponding conductive structures 2231 and 2261. In this example, two interconnect structures (e.g., interconnect structures 2293 and 2295) among the set of interconnect structures 181₁ through 181_{M} of the memory device 100 of FIG. 1 are individually electrically coupled to a respective data line (e.g., data line 2285) from among the set of data lines 170₁ through 170₉ and a data line (e.g., data line 2289) from among the set of data lines 171₁ through 171₉ of the memory device 100 of FIG. 1.

As shown in FIG. 22A and FIG. 22B, the data lines in a stack of data lines and the interconnect structures in a stack of interconnect structures may be electrically separated from each other by respective material among materials 681 through 689 that are formed in the process described with reference to FIG. 6 or among materials 1311 through 1317 that are formed in the process described with reference to FIG. 13. The data lines in a stack of data lines and interconnect structures in a stack of interconnect structures in FIG. 22A and FIG. 22B may be electrically separated from each other by a dielectric structure that includes at least one spacer among spacers 1145 (formed in the process described with reference to FIG. 11), spacers 1845 (formed in the process described with reference to FIG. 18), and spacers 1945 (formed in the process described with reference to FIG. 19). For example, the stack of data lines in FIG. 22A that includes data lines 2276 and 2278 may be electrically separated from each other by a dielectric structure that includes spacers 1145 adjacent respective sides (e.g., left and right sides) of the stack of data lines that includes data lines 2276 and 2278.

Still referring to FIG. 22A and FIG. 22B, the dielectric spacers 1145, 1845, and 1945 that electrically isolate the individual data lines 2271 through 2279 and 2281 through 2289 and the individual interconnect structures 2291 through 2296 may also electrically separate the individual conductive structures 2231, 2241, 2251, and 2261 from the data lines 2271 through 2279 and 2281 through 2289 except for an individual corresponding data line 2271 through 2279 or 2281 through 2289, and from the interconnect structures 2291 through 2296 except for an individual corresponding interconnect structure 2291 through 2296, coupled to that conductive structure 2231, 2241, 2251, or 2261. For example, the dielectric spacers 1145 and 1945 may electrically separate an individual conductive structure 2251 from the data lines 2271 through 2279 except for an individual corresponding data line 2271 through 2279.

Thus, the process acts associated with FIG. 22A and FIG. 22B may form stacks of data lines 2271 through 2279 and data lines 2281 through 2289 and stacks of interconnect structures 2291 through 2296 from materials 681 through 690, materials 1311 through 1317, and conductive structures 2241, 2251, 2231, and 2261 of the microelectronic device structure 500. The conductive structures may be in electrical contact with (electrically coupled to) the stacks of data lines 2271 through 2279 and 2281 through 2289, stacks of interconnect structures 2291 through 2296, and respective conductive contacts 540₁ through 540₉, 523, 524, 535, 536, 547, 548, 562₁ through 562₉, and 559 of the microelectronic device structure 500.

The conductive structures may be located on respective sides of individual stacks of data lines and/or individual stacks of interconnect structures. For example, conductive structures 2261 of FIG. 22B may be located on respective sides (e.g., left and right sides) of the stack of data lines that includes data lines 2286 and 2288.

Following the process acts described with reference to FIG. 22A and FIG. 22B, an additional material (e.g., silicon dioxide) (not shown) may be formed on top (e.g., in the Z-direction) of material 1317.

Thus, in accordance with embodiments of the disclosure, a microelectronic device comprises a first deck, a second deck, and a first conductive structure. The first deck has one or more memory cell strings and a stack of data lines operably connected to the one or more memory cell strings. Each of the one or more memory cell strings includes a first conductive contact. The second deck is vertically adjacent to the first deck and includes stacked tiers of conductive material defining a first interconnect structure. The first interconnect structure is operably connected to a data line of the stack of data lines. The first conductive structure is electrically coupled to the first conductive contact of the first deck and to the first interconnect structure of the second deck.

Further, in accordance with embodiments of the disclosure, a method of forming a microelectronic device comprises forming a first deck and forming a second deck. Forming the first deck comprises forming tiers of dielectric materials interleaved with tiers of conductive materials of the first deck stacked over one another, forming a first conductive structure electrically coupled to a conductive contact and to a first tier of conductive material of the tiers of conductive materials of the first deck, and forming a dielectric structure electrically separating the first conductive structure from the tiers of conductive materials of the first deck except the first tier of conductive material. Forming the second deck comprises forming tiers of dielectric materials interleaved with tiers of conductive materials of the second deck stacked over one another and forming a second conductive structure electrically coupled to the first conductive structure and to a second tier of conductive material of the tiers of conductive materials of the second deck. The second tier of conductive material defines an interconnect structure.

In various embodiments of the disclosure, multiple decks are formed one above another (e.g., in the Z-direction). As shown in FIG. 22A and FIG. 22B, decks 500A and 500B are vertically aligned in such a way as to electrically couple conductive structures 2241 to conductive structures 2251, respectively, and to electrically couple conductive structures 2231 to conductive structures 2261, respectively. When additional decks are stacked on top (e.g., in the Z-direction) of other decks, alignment of respective conductive structures may provide electrical conductivity, as desired, between any two selected decks via a continuous sequence of coupled conductive structures.

As discussed above with respect to FIG. 1-FIG. 4, FIG. 22A, and FIG. 22B, interconnect structures 181₁ through 181_{M} may be electrically coupled to data lines 170₁ through 170_{N} through one or more conductive structures 2241, 2251, 2231, and 2261 of the memory device 100 or of the microelectronic device structure 500. Thus, when interconnect structures are desired to be electrically coupled with one or more data lines, interconnect structures 2291 through 2296 and conductive structures 2231 as depicted in FIG. 22B may be formed on the memory device 100 or the microelectronic device structure 500. However, in some cases, it may be desirable to provide conductive structures to electrically couple nonadjacent decks (e.g., two or more decks separated in the Z-direction by at least one intervening deck). In such cases, conductive structures 2241 as depicted in FIG. 22A, may be formed on the memory device 100 or the microelectronic device structure 500. Such conductive structures 2241 individually comprise a vertical structure having no (e.g., lacking) electrical coupling to any of tiers of materials 1301 through 1306, the conductive structures being insulated therefrom by vertical dielectric spacers 1945 on side walls of respective openings 1911 through 1919. In some embodiments, a portion of the memory device 100 has, together in the same deck, interconnect structures 2291 through 2296 with corresponding conductive structures 2231 and conductive structures 2241 that are electrically isolated from any of tiers of materials 1301 through 1306.

Conductive structures 2241, 2251, 2231, and 2261 may provide electrically conductive coupling between and within any two selected decks 500A, 500B, whether above or below the conductive structures 2241, 2251, 2231, or 2261. In other words, conductive structures 2241, 2251, 2231, and 2261 may electrically couple interconnect structures 181₁ through 181_{M} with other components (e.g., data lines, other interconnect structures, other structures within the same block, or structures in other blocks) below or above (e.g., in the Z-direction) the deck 500A, 500B of interconnect structures 181₁ through 181_{M} and conductive structures 2241, 2251, 2231, or 2261, or on the same elevation as the deck 500A, 500B.

In some cases, it may be desirable to provide access to one or more lower decks (e.g., in the Z-direction) in order to complete material formation (e.g., depositing) process acts and/or material removal (e.g., exhuming) process acts. In such cases, openings (e.g., openings 1911 through 1919) may provide access to one or more lower decks. When additional decks are stacked on top (e.g., in the Z-direction) of other decks, alignment of respective openings 1911 through 1919 may provide access, as desired, to any selected deck(s) via a continuous sequence of vertically aligned (e.g., in the Z-direction) openings 1911 through 1919. In other embodiments, access may be provided between upper and lower (e.g., in the Z-direction) decks by way of combinations of vertical openings and horizontal openings that jointly provide a continuous sequence of openings.

Thus, in accordance with embodiments of the disclosure, a microelectronic device comprises a first deck and a second deck. The first deck includes a first conductive contact, a second conductive contact, a first stack of materials, a first conductive structure, and a second conductive structure. The second conductive contact is horizontally adjacent to the first conductive contact. The first stack of materials has tiers of conductive material interleaved with tiers of dielectric material. The first stack of materials is located over the first conductive contact and the second conductive contact. The first conductive structure is located on a first side of the first stack of materials. The first conductive structure is in contact with the first conductive contact and in contact with a first tier of the conductive material of the first stack of materials. The second conductive structure is located on a second side of the first stack of materials, opposite the first side of the first stack of materials. The second conductive structure is in contact with the second conductive contact and in contact with a second tier of the conductive material of the first stack of materials. The second deck is above the first deck and includes a second stack of materials, a third conductive structure, and a fourth conductive structure. The second stack of materials has tiers of conductive material interleaved with tiers of dielectric material. The second stack of materials define a stack of interconnect structures. The third conductive structure is located on a first side of the second stack of materials. The third conductive structure is in contact with the first conductive structure and in contact with a first tier of the conductive material of the second stack of materials. The fourth conductive structure is located on a second side of the second stack of materials, opposite the first side of the second stack of materials. The fourth conductive structure is in contact with the second conductive structure and in contact with a second tier of the conductive material of the second stack of materials.

FIG. 23 is a simplified schematic diagram depicting a portion of an electronic signal processor device 2300 as part of a microelectronic device (e.g., an electronic signal processor device, such as a microprocessor), according to one embodiment of the disclosure. The electronic signal processor device 2300 may be a part of processors (e.g., general-purpose processor), application-specific integrated circuits (ASICs), memory controllers, or other types of semiconductor devices. As shown in FIG. 23, the electronic signal processor device 2300 may include a first (e.g., lower in the Z-direction) deck 2300A and a second (e.g., higher in the Z-direction) deck 2300B. Deck 2300A includes sets of signal processor devices 2301₁ through 2301_{N}, signal processor devices 23021 through 2302_{N}, and signal processor devices 2303₁ through 2303_{N}, while deck 2300B includes sets of stacked interconnect structures 2321₁ through 2321_{M}, interconnect structures 2322₁ through 2322_{M}, interconnect structures 2323₁ through 2323_{M}, and corresponding conductive structures 2311₁ through 2311_{M}, conductive structures 2312₁ through 2312_{M}, and conductive structures 2313₁ through 2313_{M}. Interconnect structures 2321₁ through 2321_{M}, 2322₁ through 2322_{M}, or 2323₁ through 2323_{M} may carry signals between respective signal processor devices 2301₁ through 2301_{N}, signal processor devices 2302₁ through 2302_{N}, or signal processor devices 2303₁ through 2303_{N}, between other components, parts, or blocks of electronic signal processor device 2300, or between additional microelectronic device structures.

Conductive structures 2311₁ through 2311_{M}, 2312₁ through 2312_{M}, and 2313₁ through 2313_{M} may electrically couple interconnect structures 2321₁ through 2321_{M}, 2322₁ through 2322_{M}, or 2323₁ through 2323_{M} to respective signal processor devices 2301₁ through 2301_{N}, 2302₁ through 2302_{N}, or 2303₁ through 2303_{N} at conductive contacts 2306₁ through 2306_{N}, conductive contacts 2307₁ through 2307_{N}, and conductive contacts 2308₁ through 2308_{N}. The conductive structures 2311₁ through 2311_{M}, 2312₁ through 2312_{M}, or 2313₁ through 2313_{M} may include (e.g., may be formed from) a conductive material (e.g., metal, conductively doped polysilicon, other conductive materials, or combinations thereof).

Interconnect structures 2321₁ through 2321_{M}, 2322₁ through 2322_{M}, or 2323₁ through 2323_{M} may be formed by conducting similar process acts as those described with reference to FIG. 13-FIG. 22B. As such, interconnect structures may include a conductive material. As described above, as many additional decks as desired may be serially formed on top (e.g., in the Z-direction) of deck 2300B, the subsequent deck being formed on top (e.g., in the Z-direction) of the preceding deck.

As shown in FIG. 23, the electronic signal processor device 2300 may include an equal number of signal processor devices per set among the sets of signal processor devices 2301₁ through 2301_{N}, 2302₁ through 2302_{N}, and 2303₁ through 2303_{N}. The electronic signal processor device 2300 may include varying numbers of signal processor devices among the sets of signal processor devices 2301₁ through 2301_{N}, 23021 through 2302_{N}, and 2303₁ through 2303_{N}. In FIG. 23, the label “N” (the number of signal processor devices in an individual set of signal processor devices) may be any integer greater than or equal to one (N may be equal to one (N=1) or N may be greater than one (N>1)).

The electronic signal processor device 2300 may include an equal number of interconnect structures per set among the sets (e.g., the stacks) of interconnect structures 2321₁ through 2321_{M}, 2322₁ through 2322_{M}, and 2323₁ through 2323_{M}. The electronic signal processor device 2300 may include varying numbers of interconnect structures among the sets of interconnect structures 23211 through 2321_{M}, 2322₁ through 2322_{M}, and 2323₁ through 2323_{M}. In FIG. 23, the label “M” (the number of interconnect structures in an individual set of interconnect structures) may be any integer greater than or equal to one (M may be equal to one (M=1) or M may be greater than one (M>1)).

FIG. 24 depicts a microelectronic device structure 2400 having four stacked decks (e.g., decks 2400A, 2400B, 2400C, and 2400D). Decks may be formed one after another, starting with the lowest (e.g., in the Z-direction) until the top deck (e.g., in the Z-direction) is formed. Decks 2400A, 2400B, 2400C, or 2400D may be formed by conducting similar process acts as those described with reference to FIG. 13-FIG. 22B. Individual decks 2400A, 2400B, 2400C, or 2400D may include interconnect structures 2321₁ through 2321_{M}, 2322₁ through 2322_{M}, and 2323₁ through 2323_{M} as described above with respect to FIG. 22B and/or may include conductive structures 23111 through 2311_{M}, 2312₁ through 2312_{M}, or 2313₁ through 2313_{M} as described above with respect to FIG. 22A, which may provide electrical conductivity and/or access between vertically-separated (e.g., in the Z-direction) decks 2400A, 2400B, 2400C, or 2400D. Additional embodiments of microelectronic device structure 2400 include more than four stacked decks.

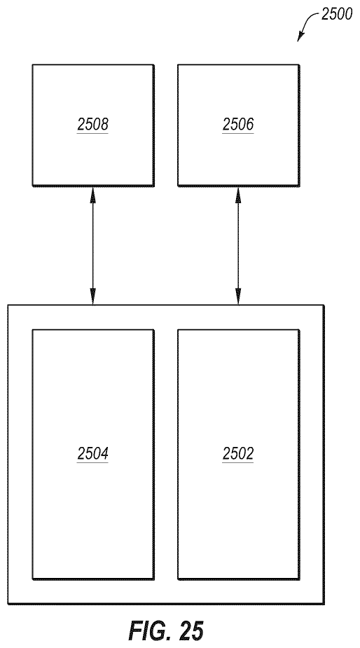

Microelectronic devices (e.g., memory device 100, electronic signal processor device 2300 previously described with reference to FIG. 1-FIG. 4 and FIG. 23) and microelectronic device structures (e.g., microelectronic device structure 500, microelectronic device structure 2400 previously described with reference to FIG. 5-FIG. 22B and FIG. 24) in accordance with embodiments of the disclosure may be used in electronic systems. For example, FIG. 25 is a block diagram of an electronic system 2500. The electronic system 2500 may comprise a computer or computer hardware component, a server or other networking hardware component, a cellular telephone, a digital camera, a personal digital assistant (PDA), a portable media (e.g., music) player, a Wi-Fi or cellular-enabled tablet such as, for example, an iPad® or SURFACE® tablet, an electronic book, or a navigation device. The electronic system 2500 may include at least one memory device 2502. The memory device 2502 may comprise, for example, one or more microelectronic devices (e.g., the memory device 100, the microelectronic device structure 500, the electronic signal processor device 2300, and the microelectronic device structure 2400 previously described with reference to FIG. 1-FIG. 24). The electronic system 2500 may further include at least one electronic signal processor device 2504 (often referred to as a “microprocessor”). The electronic signal processor device 2504 may include one or more microelectronic devices (e.g., the memory device 100, the microelectronic device structure 500, the electronic signal processor device 2300, and the microelectronic device structure 2400 previously described with reference to FIG. 1-FIG. 24).

While the memory device 2502 and the electronic signal processor device 2504 of the electronic system 2500 are depicted as two (2) discrete (e.g., separate) devices in FIG. 25, in additional embodiments, a single (e.g., only one) memory/processor device having the functionalities of the memory device 2502 and the electronic signal processor device 2504 is included in the electronic system 2500. In such embodiments, the memory/processor device includes one or more of a microelectronic device (e.g., as previously described with reference to FIG. 1-FIG. 24). The electronic system 2500 may further include one or more input devices 2506 for inputting information into the electronic system 2500 by a user, such as, for example, a mouse or other pointing device, a keyboard, a touchpad, a button, or a control panel. The electronic system 2500 may further include one or more output devices 2508 for outputting information (e.g., visual or audio output) to a user such as, for example, a monitor, a display, a printer, an audio output jack, a speaker, etc. In some embodiments, the input device 2506 and the output device 2508 comprise a single touchscreen device that may be used both to input information to the electronic system 2500 and to output visual information to a user. The input device 2506 and the output device 2508 may communicate electrically with one or more of the memory device 2502 and the electronic signal processor device 2504.

The structures, devices, and methods of the disclosure may advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other disclosed embodiments while still being encompassed within the scope of the disclosure.

What is claimed is:

1. A microelectronic device, comprising:
a first deck comprising one or more memory cell strings and a stack of data lines operably connected to the one or more memory cell strings, each of the one or more memory cell strings comprising a first conductive contact;
a second deck vertically adjacent to the first deck and comprising stacked tiers of conductive material defining a first interconnect structure operably connected to a data line of the stack of data lines; and
a first conductive structure electrically coupled to the first conductive contact of the first deck and to the first interconnect structure of the second deck.

2. The microelectronic device of claim 1, wherein the first conductive contact of the first deck is electrically coupled to a corresponding data line of the stack of data lines in the first deck.

3. The microelectronic device of claim 1, wherein the second deck is stacked above the first deck.

4. The microelectronic device of claim 1, wherein the first interconnect structure is in a vertical stack of interconnect structures in the second deck.

5. The microelectronic device of claim 1, wherein the first conductive contact of the first deck comprises a drain contact of the one or more memory cell strings.

6. The microelectronic device of claim 1, wherein:
the first deck comprises additional stacks of data lines, each of the additional stacks of data lines comprising multiple additional data lines;
the second deck comprises multiple stacks of interconnect structures, each of the multiple stacks of interconnect structures comprising multiple additional interconnect structures;
each additional data line of the additional stacks of data lines is respectively coupled to a corresponding memory cell string of the one or more memory cell strings; and
each additional interconnect structure of the multiple stacks of interconnect structures is respectively coupled to a corresponding additional data line of the additional stacks of data lines.

7. The microelectronic device of claim 1, further comprising:
a third deck stacked above the second deck, the third deck comprising stacked tiers of conductive material defining a second interconnect structure;
a second conductive structure in the second deck, the second conductive structure being electrically insulated by insulative material of the second deck; and
a second conductive contact in the first deck electrically coupled to the second interconnect structure via the second conductive structure.

8. The microelectronic device of claim 1, wherein the first interconnect structure comprises a landing pad in contact with the first conductive structure.

9. A method of forming a microelectronic device comprising:
forming a first deck, comprising:
forming tiers of dielectric materials interleaved with tiers of conductive materials of the first deck stacked over one another;
forming a first conductive structure electrically coupled to a conductive contact and to a first tier of conductive material of the tiers of conductive materials of the first deck; and
forming a dielectric structure electrically separating the first conductive structure from the tiers of conductive materials of the first deck except the first tier of conductive material; and
forming a second deck, comprising:
forming tiers of dielectric materials interleaved with tiers of conductive materials of the second deck stacked over one another; and
forming a second conductive structure electrically coupled to the first conductive structure and to a second tier of conductive material of the tiers of conductive materials of the second deck, the second tier of conductive material defining an interconnect structure.

10. The method of claim 9, further comprising:
forming a hard mask over the tiers of conductive materials of the second deck and the tiers of dielectric materials interleaved with the tiers of the conductive materials of the second deck; and
forming the interconnect structure under the hard mask.

11. The method of claim 9, further comprising:
forming an etch-stop material, the etch-stop material positioned:
above the tiers of conductive materials of the first deck, the tiers of dielectric materials interleaved with the tiers of the conductive materials of the first deck, and the first conductive structure; and
below the tiers of conductive materials of the second deck, the tiers of dielectric materials interleaved with the tiers of the conductive materials of the second deck, and the second conductive structure.

12. The method of claim 9, further comprising:
forming a third conductive structure in the first deck, the third conductive structure being electrically coupled to a second conductive contact in the first deck;
forming a fourth conductive structure in the second deck, the fourth conductive structure being electrically coupled to the third conductive structure;
electrically separating the fourth conductive structure from the tiers of conductive materials of the second deck; and
forming a third deck, comprising:
forming tiers of conductive materials of the third deck stacked over one another;
forming tiers of dielectric materials interleaved with the tiers of the conductive materials of the third deck; and
forming a fifth conductive structure in the third deck, the fifth conductive structure being electrically coupled to the fourth conductive structure and to a third tier of conductive material of the tiers of conductive materials of the third deck, the third tier of conductive material defining a second interconnect structure.

13. The method of claim 9, wherein forming the second deck further comprises forming a second dielectric structure electrically separating the second conductive structure from the tiers of conductive materials of the second deck except the second tier of conductive material.

14. The method of claim 9, wherein forming the second deck further comprises forming a staircase structure in the tiers of conductive materials of the second deck and the tiers of dielectric materials interleaved with the tiers of the conductive materials of the second deck.

15. A microelectronic device, comprising
a first deck, comprising:
a first conductive contact;
a second conductive contact horizontally adjacent to the first conductive contact;
a first stack of materials comprising tiers of conductive material interleaved with tiers of dielectric material, the first stack of materials located over the first conductive contact and the second conductive contact;
a first conductive structure located on a first side of the first stack of materials, the first conductive structure in contact with the first conductive contact and in contact with a first tier of the conductive material of the first stack of materials; and
a second conductive structure located on a second side of the first stack of materials, opposite the first side of the first stack of materials, the second conductive structure in contact with the second conductive contact and in contact with a second tier of the conductive material of the first stack of materials;
a second deck above the first deck, the second deck comprising:
a second stack of materials comprising tiers of conductive material interleaved with tiers of dielectric material, the second stack of materials defining a stack of interconnect structures;
a third conductive structure located on a first side of the second stack of materials, the third conductive structure in contact with the first conductive structure and in contact with a first tier of the conductive material of the second stack of materials; and
a fourth conductive structure located on a second side of the second stack of materials, opposite the first side of the second stack of materials, the fourth conductive structure in contact with the second conductive structure and in contact with a second tier of the conductive material of the second stack of materials.

16. The microelectronic device of claim 15, wherein the microelectronic device comprises a memory device.

17. The microelectronic device of claim 15, wherein the first deck comprises a signal processor device.

18. The microelectronic device of claim 15, wherein the first deck comprises a memory device.

19. The microelectronic device of claim 18, wherein the memory device comprises:
one or more data lines; and
one or more memory cells electrically coupled to the one or more data lines, respectively;
wherein:
the first conductive contact is configured as a drain contact of a first one of the one or more memory cells; and
the second conductive contact is configured as a drain contact of a second one of the one or more memory cells.

20. The microelectronic device of claim 15, further comprising an etch-stop material above the first conductive contact, the second conductive contact, and the first stack of materials; and below the second stack of materials, the third conductive structure, and the fourth conductive structure.
